(19) United States
(12) Patent Application Publication
(10) Pub. No.: US 2026/0075947 A1
(43) Pub. Date: Mar. 12, 2026

(54) DISPLAY PANEL AND FABRICATION METHOD THEREOF, AND DISPLAY DEVICE

(71) Applicant: Xiamen Tianma Optoelectronics Co., Ltd., Xiamen (CN)

(72) Inventors: Yong ZENG, Xiamen (CN); Jianming WANG, Xiamen (CN)

(21) Appl. No.: 18/940,640

(22) Filed: Nov. 7, 2024

(30) Foreign Application Priority Data
Sep. 6, 2024 (CN) 202411252414.3

(51) Int. Cl. H01L 27/12; G02F 1/1362

(52) U.S. Cl. CPC H10D 86/60; G02F 1/136209; G02F 1/136286; H10D 86/021; H10D 86/441

(57) ABSTRACT

A display panel includes: a substrate; an active layer; a first insulating layer; and a first metal layer. The first insulating layer includes a first insulating section and a second insulating section. The first metal layer includes a first electrode, a first gate and a second electrode. The active layer, the first electrode, the first gate and the second electrode form a transistor. The first electrode and the second electrode are electrically connected to the active layer. The first gate at least partially overlaps with the active layer, and at least partially overlaps with the first insulating section, and the first electrode at least partially overlaps with the second insulating section. The first gate includes a first side; and on the first side, a cut-off position of the first gate is the same as a cut-off position of the first insulating section.

### CROSS-REFERENCE TO RELATED APPLICATION

This application claims the priority of Chinese Patent Application No. 202411252414.3, filed on Sep. 6, 2024, the content of which is incorporated herein by reference in its entirety.

### TECHNICAL FIELD

The present disclosure generally relates to the field of display technology and, more particularly, relates to a display panel and its fabrication method, and a display device.

### BACKGROUND

With the continuous development of display technology, display panels have been widely used in people's production and life. To better meet people's needs, display panels can be adjusted, such as adjusting film layers in the display panels, to improve the display panels' overall effect.

### SUMMARY

One aspect of the present disclosure provides a display panel. The display panel includes: a substrate; an active layer on a side of the substrate; a first insulating layer on a side of the active layer away from the substrate; and a first metal layer on a side of the first insulating layer away from the substrate. The first insulating layer includes a first insulating section and a second insulating section. The first metal layer includes a first electrode, a first gate and a second electrode. The display panel includes a transistor, and the transistor includes the active layer, the first electrode, the first gate and the second electrode. The first electrode and the second electrode are both electrically connected to the active layer. Along a first direction, the first gate at least partially overlaps with the active layer, the first gate at least partially overlaps with the first insulating section, and the first electrode at least partially overlaps with the second insulating section. The first direction is a direction perpendicular to a plane where the substrate is located. The first gate includes a first side; and on the first side, a cut-off position of the first gate is the same as a cut-off position of the first insulating section.

Another aspect of the present disclosure provides a fabrication method of a display panel. The method includes: providing a substrate; forming an active layer on a side of the substrate; forming a first insulating film layer on a side of the active layer away from the substrate; forming a first metal layer on a side of the first insulating film layer away from the substrate; and using the first metal layer as a mask to etch the first insulating film layer to form a first insulating layer. The first metal layer includes a first electrode, a first gate, and a second electrode. The display panel includes a transistor and the transistor includes the active layer, the first electrode, the first gate, and the second electrode. The first electrode and the second electrode are both electrically connected to the active layer. The first insulating layer includes a first insulating section and a second insulating section. Along a first direction, the first gate at least partially overlaps with the active layer, the first gate at least partially overlaps with the first insulating section, and the first electrode at least partially overlaps with the second insulating section, where the first direction is a direction perpendicular to the plane where the substrate is located.

Another aspect of the present disclosure provides a display device. The display device includes a display panel. The display panel includes: a substrate; an active layer on a side of the substrate; a first insulating layer on a side of the active layer away from the substrate; and a first metal layer on a side of the first insulating layer away from the substrate. The first insulating layer includes a first insulating section and a second insulating section. The first metal layer includes a first electrode, a first gate and a second electrode. The display panel includes a transistor, and the transistor includes the active layer, the first electrode, the first gate and the second electrode. The first electrode and the second electrode are both electrically connected to the active layer. Along a first direction, the first gate at least partially overlaps with the active layer, the first gate at least partially overlaps with the first insulating section, and the first electrode at least partially overlaps with the second insulating section. The first direction is a direction perpendicular to a plane where the substrate is located. The first gate includes a first side; and on the first side, a cut-off position of the first gate is the same as a cut-off position of the first insulating section.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates an exemplary display panel consistent with various disclosed embodiments in the present disclosure.

FIG. 2 illustrates an exemplary transistor consistent with various disclosed embodiments in the present disclosure.

FIG. 3 illustrates a cross-sectional view along an A-A′ direction in FIG. 2 consistent with various disclosed embodiments in the present disclosure.

FIG. 4 illustrates another cross-sectional view along an A-A′ direction in FIG. 2 consistent with various disclosed embodiments in the present disclosure.

FIG. 5 illustrates a fabrication process along an A-A′ direction in FIG. 2 consistent with various disclosed embodiments in the present disclosure.

FIG. 6 illustrates a cross-sectional view along a B-B′ direction in FIG. 2 consistent with various disclosed embodiments in the present disclosure.

FIG. 7 illustrates another exemplary display panel consistent with various disclosed embodiments in the present disclosure.

FIG. 8 illustrates another exemplary display panel consistent with various disclosed embodiments in the present disclosure.

FIG. 9 illustrates a cross-sectional view along a C-C′ direction in FIG. 8 consistent with various disclosed embodiments in the present disclosure.

FIG. 10 illustrates another exemplary display panel consistent with various disclosed embodiments in the present disclosure.

FIG. 11 illustrates a cross-sectional view along a D-D′ direction in FIG. 8 consistent with various disclosed embodiments in the present disclosure.

FIG. 12 illustrates another exemplary display panel consistent with various disclosed embodiments in the present disclosure.

FIG. 13 illustrates a cross-sectional view along an E-E′ direction in FIG. 12 consistent with various disclosed embodiments in the present disclosure.

FIG. 14 illustrates a cross-sectional view along an F-F′ direction in FIG. 12 consistent with various disclosed embodiments in the present disclosure.

FIG. 15 illustrates another exemplary display panel consistent with various disclosed embodiments in the present disclosure.

FIG. 16 illustrates another exemplary display panel consistent with various disclosed embodiments in the present disclosure.

FIG. 17 illustrates an exemplary scan signal line in FIG. 16 consistent with various disclosed embodiments in the present disclosure.

FIG. 18 illustrates another exemplary display panel consistent with various disclosed embodiments in the present disclosure.

FIG. 19 illustrates an exemplary scan signal line in FIG. 18 consistent with various disclosed embodiments in the present disclosure.

FIG. 20 illustrates another exemplary scan signal line in FIG. 18 consistent with various disclosed embodiments in the present disclosure.

FIG. 21 illustrates another exemplary display panel consistent with various disclosed embodiments in the present disclosure.

FIG. 22 illustrates a cross-sectional view along a G-G′ direction in FIG. 21 consistent with various disclosed embodiments in the present disclosure.

FIG. 23 illustrates another cross-sectional view along a G-G′ direction in FIG. 21 consistent with various disclosed embodiments in the present disclosure.

FIG. 24 illustrates another cross-sectional view along a G-G′ direction in FIG. 21 with various disclosed embodiments in the present disclosure.

FIG. 25 illustrates another exemplary display panel consistent with various disclosed embodiments in the present disclosure.

FIG. 26 illustrates another exemplary display panel consistent with various disclosed embodiments in the present disclosure.

FIG. 27 illustrates a local structure of an H region in FIG. 8 consistent with various disclosed embodiments in the present disclosure.

FIG. 28 illustrates another exemplary display panel consistent with various disclosed embodiments in the present disclosure.

FIG. 29 illustrates another exemplary display panel consistent with various disclosed embodiments in the present disclosure.

FIG. 30 illustrates another exemplary display panel consistent with various disclosed embodiments in the present disclosure.

FIG. 31 illustrates another exemplary display panel consistent with various disclosed embodiments in the present disclosure.

FIG. 32 illustrates another cross-sectional view along an A-A′ direction in FIG. 2 consistent with various disclosed embodiments in the present disclosure.

FIG. 33 illustrates a top view of an exemplary active layer consistent with various disclosed embodiments in the present disclosure.

FIG. 34 illustrates another exemplary transistor consistent with various disclosed embodiments in the present disclosure.

FIG. 35 illustrates a top view of another exemplary active layer consistent with various disclosed embodiments in the present disclosure.

FIG. 36 illustrates another exemplary display panel consistent with various disclosed embodiments in the present disclosure.

FIG. 37 illustrates a cross-sectional view along an H-H′ direction in FIG. 36 consistent with various disclosed embodiments in the present disclosure.

FIG. 38 illustrates another cross-sectional view along an H-H′ direction in FIG. 36 consistent with various disclosed embodiments in the present disclosure.

FIG. 39 illustrates a cross-sectional view of an exemplary transistor consistent with various disclosed embodiments in the present disclosure.

FIG. 40 illustrates an enlarged view of an H region in FIG. 8 consistent with various disclosed embodiments in the present disclosure.

FIG. 41 illustrates a cross-sectional view along an I-I′ direction in FIG. 40 consistent with various disclosed embodiments in the present disclosure.

FIG. 42 illustrates another enlarged view of an H region in FIG. 8 consistent with various disclosed embodiments in the present disclosure.

FIG. 43 illustrates a cross-sectional view along a J-J′ direction in FIG. 42 consistent with various disclosed embodiments in the present disclosure.

FIG. 44 illustrates another enlarged view of an H region in FIG. 8 consistent with various disclosed embodiments in the present disclosure.

FIG. 45 illustrates a cross-sectional view along a K-K′ direction in FIG. 44 consistent with various disclosed embodiments in the present disclosure.

FIG. 46 illustrates another cross-sectional view along an I-I′ direction in FIG. 40 consistent with various disclosed embodiments in the present disclosure.

FIG. 47 illustrates a flowchart of an exemplary fabrication method of a display panel consistent with various disclosed embodiments in the present disclosure.

FIG. 48 illustrates cross-sectional views of a display panel corresponding to different stages of an exemplary fabrication method of a display panel, consistent with various disclosed embodiments in the present disclosure.

FIG. 49 illustrates top views of a display panel corresponding to different stages of an exemplary fabrication method of a display panel, consistent with various disclosed embodiments in the present disclosure.

FIG. 50 illustrates a flowchart of another exemplary fabrication method of a display panel consistent with various disclosed embodiments in the present disclosure.

FIG. 51 illustrates an exemplary display device consistent with various disclosed embodiments in the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like parts, and a detailed description thereof may be omitted. Further, in the present disclosure, the disclosed embodiments and the features of the disclosed embodiments may be combined under conditions without conflicts. It is apparent that the described embodiments are some but not all of the embodiments of the present disclosure. Based on the disclosed embodiments, persons of ordinary skill in the art may derive other embodiments consistent with the present disclosure, all of which are within the scope of the present disclosure.

Moreover, the present disclosure is described with reference to schematic diagrams. For the convenience of descriptions of the embodiments, the cross-sectional views illustrating the device structures may not follow the common proportion and may be partially exaggerated. Besides, those schematic diagrams are merely examples, and not intended to limit the scope of the disclosure. Furthermore, a three-dimensional (3D) size including length, width, and depth should be considered during practical fabrication.

In the present disclosure, terms such as “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential”, etc., indicate orientations or positional relationships based on the orientations or positional relationships shown in the accompanying drawings, and are only for the convenience of describing the present disclosure and simplifying the description, and do not indicate or imply that the device or element referred to must have a specific orientation, be constructed and operated in a specific orientation, and therefore should not be understood as limiting the present disclosure.

In the present disclosure, relational terms such as first and second are only used to distinguish one entity or operation from another entity or operation, and do not necessarily require or imply any such actual relationship between these entities or operations or order. Moreover, the terms “including”, “comprising” or any other variants thereof are intended to cover non-exclusive inclusion, such that a process, method, article, or device that includes a series of elements includes not only those elements, but also those that are not explicitly listed or also include elements inherent to this process, method, article or equipment. If there are no more restrictions, the elements defined by the sentence “including . . . ” do not exclude the existence of other same elements in the process, method, article, or equipment that includes the elements.

It should be understood that when describing the structure of a component, when a layer or region is referred to as being “on” or “above” another layer or another region, the layer or region may be directly on the other layer or region, or indirectly on the other layer or region, for example, layers/components between the layer or region and another layer or another region. And, for example, when the component is reversed, the layer or region may be “below” or “under” the other layer or region. In the present disclosure, the term “electrical connection” refers to that two components are directly electrically connected with each other, or the two components are electrically connected via one or more other components.

In the present disclosure, unless otherwise clearly specified and limited, the terms “installed”, “connected”, “fixed” and the like appear, should be understood in a broad sense. For example, it can be a fixed connection, a detachable connection, or an integrated connection; it can be a mechanical connection or an electrical connection; it can be a direct connection or an indirect connection through an intermediate medium, it can be the internal connection of two elements or the interaction relationship between two elements, unless otherwise clearly defined. For those skilled in the art, the specific meanings of the above terms in the present disclosure can be understood according to the specific circumstances.

In the present disclosure, when an element is referred to as being “fixed to” or “disposed on” another element, it may be directly on the other element or there may be an intermediate element. When an element is considered to be “connected to” another element, it may be directly connected to the other element or there may be an intermediate element at the same time. If present, the terms “vertical”, “horizontal”, “upper”, “lower”, “left”, “right” and similar expressions are for illustrative purposes only and are not intended to be the only embodiment.

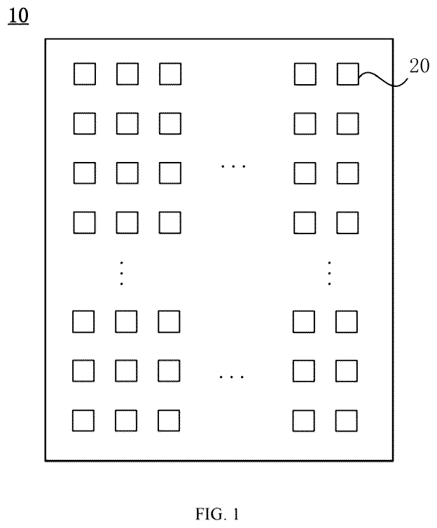

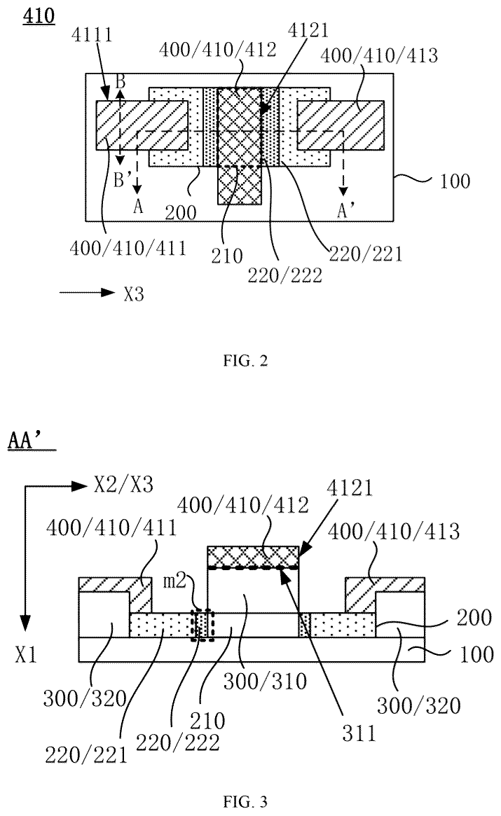

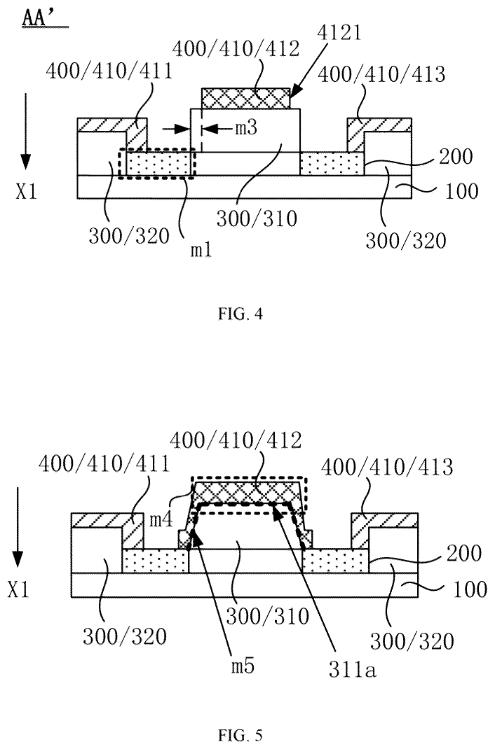

The present disclosure provides a display panel. In one embodiment as shown in FIG. 1, which illustrates an exemplary display panel; FIG. 2, which illustrates a top view of an exemplary transistor, FIG. 3 which is a cross-sectional view along an A-A′ direction in FIG. 2, and FIG. 4 which is another cross-sectional view along the A-A′ direction in FIG. 2, the display panel 10 may include: a substrate 100; an active layer 200 located on one side of the substrate 100; a first insulating layer 300 located on a side of the active layer 200 away from the substrate 100, and includes a first insulating section 310 and a second insulating section 320; a first metal layer 400 located on a side of the first insulating layer 300 away from the substrate, and including a first electrode 411, a first gate 412 and a second electrode 413. The display panel 10 may also include a transistor 410 which includes the active layer 200, the first electrode 411, the first gate 412 and the second electrode 413. The first electrode 411 and the second electrode 413 may electrically connect to the active layer 200. Along the first direction X1, the first gate 412 may at least partially overlap with the active layer 200 and may at least partially overlap with the first insulating section 310, and the first electrode 411 may at least partially overlap with the second insulating section 320. The first gate 412 may include a first side 4121, and on the first side 4121, the cut-off position of the first gate 412 may be the same as the cut-off position of the first insulating section 310. The first direction X1 may be a direction perpendicular to the plane where the substrate 100 is located.

As shown in FIG. 3, the display panel 10 may include the substrate 100 and film structures such as the metal layer and the insulating layer on one side of the substrate 100. For example, the display panel may include the active layer 200, the first insulating layer 300 and the first metal layer 400. The active layer 200 may be located on one side of the substrate 100, and the first metal layer 300 may be located on a side of the active layer 200 away from the substrate 100. The active layer 200 may be made of a material including silicon or metal oxide, such as indium gallium zinc oxide.

As shown in FIG. 1 to FIG. 3, the display panel 10 may include the transistors 410, and one transistor 410 may include an active layer 200, a first electrode 411, a first gate 412, and a second electrode 413. The first electrode 411 and the second electrode 413 may both be electrically connected to the active layer 200, and the first gate 412 may at least partially overlap the active layer 200 along the first direction X1. It should be noted that FIGS. 2 and 3 only show a relative position relationship between the first electrode 411, the first gate 412, and the second electrode 413. For different transistors 410, the relative positions of the first electrode 411, the first gate 412, and the second electrode 413 may be diverse, and the embodiments of the present disclosure are not illustrated one by one here. The control signal received by the first gate 412 of the transistor 410 may be used to control the turn-on or turn-off of the transistor 410. The first electrode 411 of the transistor 410 may be one of the source or the drain, and the second electrode 413 of the transistor 410 may be the other of the source or the drain. The display panel 10 may include a plurality of pixels 20 arranged in an array. One pixel 20 may include one transistor 410. The display function of the display panel 10 may be achieved by controlling the on and off state of the transistor 410.

The display panel 10 may further include a driving circuit (not specifically shown in the figure), and the driving circuit may include the above-mentioned transistor 410. The driving circuit may be a pixel circuit or a peripheral driving circuit. The peripheral driving circuit may include a shift register circuit, an electrostatic protection circuit, a visual test circuit, etc. Taking the pixel circuit as an example, the pixel circuit may include at least one transistor 410. When the display panel is a liquid crystal display panel, the transistor 410 included in the pixel circuit may be connected between the data signal line and the pixel electrode, and the gate of the transistor 410 may be connected to the gate signal line. Under the control of the signal provided by the gate signal line, the data signal provided by the data signal line may be transmitted to the pixel electrode, and the pixel electrode and the common electrode may generate an electric field for controlling the rotation of the liquid crystal molecules. In another embodiment, for example, the display panel may be an organic light-emitting display panel (OLED) or an inorganic light-emitting diode display panel (LED), and the pixel circuit may be a circuit such as a 7T1C circuit, which drives the light-emitting element to emit light by providing a driving current to the light-emitting element.

As shown in FIG. 2 and FIG. 3, in one embodiment, the first metal layer 400 may include the first electrode 411, the first gate 412, and the second electrode 413. That is, the first electrode 411, the first gate 412, and the second electrode 413 in the transistor 410 may all be prepared simultaneously by using the same process when preparing the first metal layer 400. Compared with the process in which the preparation of the gate is performed separately from the preparation of the source/drain electrodes, the process preparation cost of the display panel 10 may be reduced. Further, the first insulating layer 300 may include a first insulating section 310 and a second insulating section 320. Along the first direction X1, the first gate 412 may at least partially overlap with the first insulating section 310, the first electrode 411 may at least partially overlap with the second insulating section 320, and the second electrode 413 may overlap with another second insulating section 320. Furthermore, the first electrode 411, the first gate 412 and the second electrode 413 may all be located on the side of the first insulating layer 300 away from the substrate 100, that is, the first gate 412, the first electrode 411 and the second electrode 413 may be arranged in the same layer, which is beneficial to realize the thin design of the display panel 10.

As shown in FIG. 2 and FIG. 3, the first gate 412 may include a first side 4121, and the first side 4121 may be understood as a side edge of the first gate 412. As shown in FIG. 3, on the first side 4121, the cut-off position of the first gate 412 may be the same as the cut-off position of the first insulating section 310, that is, the morphology of the first gate 412 and the first insulating section 310 may be consistent. The cut-off position of the first gate 412 may be the edge of the pattern of the first gate 412; and the cut-off position of the first insulating section 310 may be the edge of the pattern of the first insulating section 310. That is, the morphology of the edge of the first gate 412 and the first insulating section 310 may be consistent, which reflects the regularity of the overall structure of the display panel 10.

The morphology of the first insulating section 310 and the morphology of the first gate 412 that are consistent may be achieved through a self-alignment process. Exemplarily, as shown in FIG. 4 illustrating the display panel 10 after the first electrode 411, the first gate 412 and the second electrode 413 are prepared and before the insulating layer is etched again, the first metal layer 400 may be used as a mask to etch the first insulating layer 300, that is, the first insulating layer 300 that is not covered by the metal patterns of the first metal layer 400 and exposed to the outside may be etched, to adjust the morphology of the first insulating section 310, that is, to perform a self-alignment process to ensure that the edge morphology of the first gate 412 and the first insulating section 310 are consistent. Comparing FIG. 3 and FIG. 4, the cut-off position of the first insulating section 310 may be made the same as the cut-off position of the first gate 412 through a self-alignment process, thereby ensuring the regularity of the overall structure of the display panel 10. Optionally, when a self-alignment process is adopted and the first gate 412 is used as a standard to etch the first insulating section 310, there may be process errors. Therefore, when the distance between the cut-off position of the first gate 412 and the cut-off position of the first insulating section 310 is less than or equal to 0.5 microns, it may be understood that the cut-off position of the first insulating section 310 is the same as the cut-off position of the first gate 412.

As shown in FIG. 2 and FIG. 3, the first electrode 411, the first gate 412 and the second electrode 413 may be arranged in the same layer, and may all be located on the side of the first insulating layer 300 away from the substrate 100. The number of film layers of the display panel 10 as a whole may be reduced, and thus reducing the overall film thickness of the display panel 10. Also, the first electrode 411, the first gate 412 and the second electrode 413 may be prepared simultaneously using the same process, which may reduce the process preparation cost of the display panel 10.

In one embodiment, the adjustment of the shape of the first insulating section 310 may be achieved by etching the first insulating layer 300 twice. As shown in FIG. 4, after the first insulating layer 300 is etched for the first time, an opening may be formed in the first insulating layer 300, as shown in the area m1 in FIG. 4. After the opening is formed in the first insulating layer 300 and before the first metal layer is prepared, the active layer 200 may be firstly made conductive (such as through ion doping). For example, the area of the active layer 200 exposed by the opening of the first insulating layer 300 may be made conductive to form a source region and a drain region, such that the source region and the drain region of the active layer may form good electrical contacts with the source and the drain formed subsequently. After the first conductive layer 200 is made conductive, the first electrode 411, the first gate 412 and the second electrode 413 in the transistor 410 may be prepared, as shown in FIG. 4. However, after the first etching, the cut-off position of the first insulating section 310 may be different from the cut-off position of the first gate 412. Along the direction parallel to the plane where the substrate 100 is located, the size of the first insulating section 310 may be larger than the size of the first gate 412. For the portion of the active layer 200 that is covered by the first insulating section 310 and does not overlap with the first gate 412 (as shown in the portion covered by the region m3 in FIG. 4), the formed transistor may have a contact resistance problem. Since this portion of the active layer 200 is covered by the first insulating section 310, it is not conductorized and cannot play the role of a conductor in the source region or the drain region. Since this portion of the active layer 200 does not overlap with the first gate 412, it cannot play the role of a channel region. This portion may be located between the source region and the channel region and between the drain region and the channel region, which causes the transistor to have a contact resistance problem and thus cannot be turned on normally. The first insulating layer 300 may be etched a second time through a self-alignment process to expose the portion of the active layer 200, which is conducive to improving the conductive properties of the portion of the active layer 200 through the second conductorization. After improvement, the portion of the active layer may be conductive, as shown in area m2 in FIG. 3.

FIG. 5 is a comparison diagram of FIG. 3. As shown in FIG. 5, when the first insulating layer 300 is etched such that a size of the first insulating section 310 is same as the size of the first gate to be formed before the first metal layer 400 is prepared, as shown in the region m4 in FIG. 5, the size of the first gate may be the same as the pattern cut-off position of the first insulating section 310, and, when the first gate is formed, the first gate may be likely to cover the side wall of the first insulating section. On the one hand, the first gate cannot form a planar structure, which affects the function of the gate. On the other hand, the part of the first gate extending to the side wall of the first insulating section may contact the active layer, causing the transistor to fail. Therefore, in the display panel provided by the present disclosure, the process of adjusting the first insulating layer 300 thereof may improve the contact resistance problem of the transistor on the one hand, and may ensure the formation of a planar gate on the other hand, thereby reducing the occurrence of transistor failure.

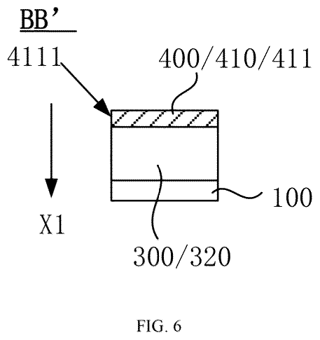

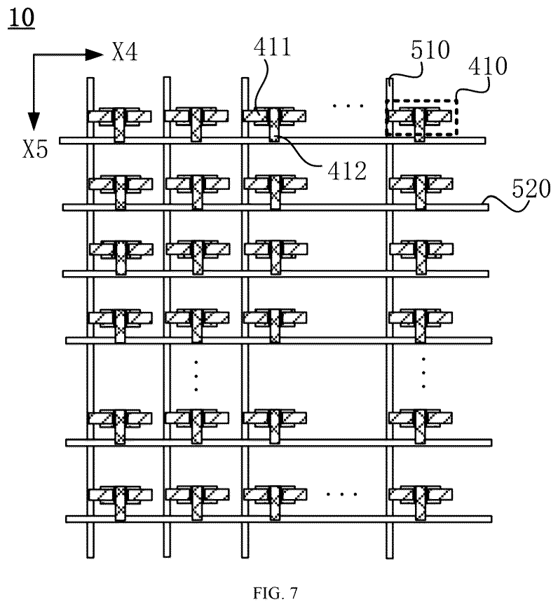

FIG. 6 is a cross-sectional schematic diagram along the section line B-B′ in FIG. 2. As shown in FIG. 2 and FIG. 6, in one embodiment, the first electrode 411 may include a second side 4111. On the second side 4111, the cut-off position of the first electrode 411 may be the same as the cut-off position of the second insulating section 320.

As shown in FIG. 2 and FIG. 6, the first electrode 411 may include a second side 4111, and the second side 4111 may be understood as a side of the first electrode 411. For example, from a top view, the shape of the first electrode 411 may be rectangular, annular or semi-annular (“U” shape), etc., and the present disclosure does not specifically limit the shape of the first electrode 411. According to different types of display panels 10 or different types of transistors 410, the shape of the first electrode 411 may be adaptively adjusted. Further, the side of the first electrode 411 may be any side of the two opposite sides along its width direction. Exemplarily, as shown in FIG. 6, the side of the first electrode 411 may be understood as: when the first electrode 411 is a strip electrode, one side of the two sides along the width direction. As shown in FIG. 6, on the second side 4111, the cut-off position of the first electrode 411 may be the same as the cut-off position of the second insulating section 320, that is, the morphology of the first electrode 411 and the second insulating section 320 may be consistent. The cut-off position of the first electrode 411 may be understood as the edge of the pattern of the first electrode 411; the cut-off position of the second insulating section 320 may be understood as the edge of the pattern of the second insulating section 320, that is, the edge morphology of the first electrode 411 and the second insulating section 320 may be consistent, thus reflecting the regularity of the overall structure of the display panel 10.

In one embodiment, the first insulating section 310 and the second insulating section 320 may be made of the same material, and the first electrode 411 and the first gate 412 may be made of the same material. The first insulating section 310 may be etched twice through the first gate 412 using a self-alignment process, such that the cut-off position of the first gate 412 is the same as the cut-off position of the first insulating section 310. Also, the second insulating section 320 may be etched twice through the first electrode 411 using a self-alignment process, such that the cut-off position of the first electrode 411 is the same as the cut-off position of the second insulating section 320.

Similarly, at least one side of the second electrode 413 has the same cut-off position as the cut-off position of another second insulating section.

In the first cross section, the cross section of the first gate 412 may intersect with the cross section of the first insulating section 310 at the first side 311, and the first side 311 may be a line segment. The first cross section may be a plane determined by the second direction X2 and the first direction X1, where the second direction X2 intersects with the first side 4121 and is parallel to the plane where the substrate 100 is located.

In one embodiment, the first cross section may be determined by the second direction X2 and the first direction X1, where the second direction X2 intersects with the first side 4121 and is parallel to the plane where the substrate 100 is located. The first cross section may be understood as the cross-sectional direction of the cross-sectional view shown in FIG. 3. As shown in FIG. 3, in the cross-sectional view, the cross sections of the first gate 412 and the first insulating section 310 may intersect at the first side 311 (as shown by the dotted line indicated in FIG. 3). The first edge 311 may be a line segment, that is, the two film layers of the first gate 412 and the first insulating section 310 may be formed by stacking film layers with flat surfaces, and may not include the part of the film layer side wall of the first insulating section 310 covered by the first gate 412. Therefore, the first gate 412 and the active layer 200 may be prevented from contacting, thereby ensuring the stability of the signal transmission of the transistor 410 and ensuring the display effect of the display panel 10.

The cut-off positions of the first gate 412 same as the cut-off position of the first insulating section 310 may be achieved through a binary process, that is, the preparation process may be shown in FIG. 3 and FIG. 4. That is, the first insulating section 310 may be etched twice, where the first etching includes etching the insulating film layer to form the first insulating section 310 and the second insulating section 320, and the second etching includes adjusting the cut-off position of the first insulating section 310 to the cut-off position of the first gate 412 through a self-alignment process. When the self-alignment process is not used, and the cut-off position of the first insulating section 310 is directly adjusted to the cut-off position of the first gate 412, the first gate 412 may cover the side wall portion of the first insulating section 310 because of the deviation in the preparation of the film layer, that is, the first edge 311 may be a broken line instead of a line segment, such that the first gate 412 may be in contact with the active layer 200 to affect the working performance of the transistor 410. As shown in FIG. 5, for example, when the size of the first insulating section 310 is directly set to be the same as the size of the first gate 412 to be formed through the first etching process, when the first gate 412 is prepared, at least part of the first gate 412 may overlap the side wall of the first insulating section 310 during the film deposition process, that is, the area indicated by the arrow m5 in FIG. 5. Therefore, the cross sections of the first gate 412 and the first insulating section 310 may intersect at the second side 311a (shown by the dotted line indicated in FIG. 5). The second side 311a may be a broken line rather than a line segment, that is, the first gate 412 covering the surface of the first insulating section 310 which includes the surface of the first insulating section 310 away from the substrate 100 and the side of the first insulating section 310. Therefore, the first gate 412 may be in contact with the active layer 200, and the stability of the signal transmission of the transistor 410 cannot be guaranteed, thereby affecting the signal transmission effect in the display panel 10. To ensure the working stability of the transistor 410, the first insulating layer 300 may be etched twice (including the second self-alignment process) in the present disclosure, which may effectively improve the contact resistance problem of the transistor 410, thereby ensuring the overall signal transmission effect of the display panel 10.

As shown in FIG. 2 and FIG. 3, the active layer 200 may include a channel region 210 and a doped region 220. In a plane parallel to the plane where the substrate 100 is located, along the third direction X3, the doped region 220 may be connected to the first gate 412 at the first side 4121 of the first gate 412, where the third direction X3 is parallel to the plane where the substrate 100 is located and intersects with the first side 4121.

For example, the active layer 200 may include the channel region 210 and the doped region 220. As shown in FIG. 2 and FIG. 3, the channel region 210 may be understood as a corresponding region of the first gate 411 in the active layer 200 along the first direction X1, and the control signal received by the first gate 411 may control the channel region 210 to be turned on or off. The doped region 220 may be understood as a region where the active layer 200 is ion-doped. The doped region 220 may be conductive, and may be able to input or output related signals (such as data signals).

As shown in FIG. 2 and FIG. 3, in one embodiment, along the third direction X3, the doped region 220 may be connected to the first gate 412 at the first side 4121 of the first gate 412, that is, the area outside the channel region 210 of the active layer 200 may be the doped region 220. It should be noted that in FIG. 3, the second direction X2 and the third direction X3 indicate the same direction. Although the second direction X2 and the third direction X3 are parallel to the plane where the substrate 100 is located, the second direction X2 indicates the direction of the cross section to be obtained, and the third direction X3 is the direction from the doped region 220 to the channel region 210. The two directions may have different meanings, but the directions may be the same in some embodiments. As shown in FIG. 3 and FIG. 4, the cut-off position of the first gate 412 may be the same as the cut-off position of the first insulating section 310. Through the self-alignment process, the occupied area of the first insulating section 310 at the active layer 200 may be reduced, and the reduced first insulating section 310 may be ion-doped again in the corresponding area of the active layer 200, thereby ensuring that the area of the doped region 220 in the active layer 200 is large enough. The display panel 10 provided by the present embodiment may improve the conductivity of the transistor 410 by increasing the area of the doped region 220 in the active layer 200, thereby ensuring the reliability of signal transmission of the display panel 10 and ensuring the display effect of the display panel 10.

As shown in FIG. 2 and FIG. 3, the doped region 220 may include a first doped section 221 and a second doped section 222. The first doped section 221 may be located on a side of the second doped section 222 away from the channel region 210. Along the first direction X1, the first doped section 221 may at least partially overlap with the first electrode 411, and the second doped section 222 may be located between the first doped section 221 and the channel region 210. The ion doping concentration of the second doped section 222 may be equal to the ion doping concentration of the first doped section 221.

For example, in one embodiment as shown in FIG. 2 and FIG. 3, the doped region 220 may include the first doped section 221 and the second doped section 222, where the first doped section 221 may be located on a side of the second doped section 222 away from the channel region 210. The first doped section 221 may at least partially overlap with the first electrode 411 along the first direction X1, that is, the first doped section 221 may be understood as a region in the active layer 200 that is transformed from a semiconductor to a conductor before the first electrode 411 is formed. The first electrode 411 may realize an electrical connection between the first electrode 411 and the active layer 200 by contacting the first doped section 221.

The second doped section 222 may be located between the first doped section 221 and the channel region 210. As shown in FIG. 3 and FIG. 4, the second doped section 222 may be understood as: a region which is included in the active layer 200 where a portion of the first insulating section 310 is removed by the self-alignment process and then is transformed from a semiconductor to a conductor by ion doping after the first insulating section 310 is subjected to a self-alignment process. Therefore, the doped region 220 of the active layer 200 may include the first doped section 221 and the second doped section 222. The first doped section 221 and the second doped section 222 may ensure the conductivity of the active layer 200, thereby ensuring the working stability of the transistor 410.

In one embodiment, the ion doping concentration of the first doped section 221 may be the same as or similar to the ion doping concentration of the second doped section 222. Therefore, the overall conductive effect of the active layer 200 may be balanced, thereby further reflecting the working stability of the transistor 410, ensuring the signal transmission effect of the display panel 10, and improving the display effect of the display panel 10.

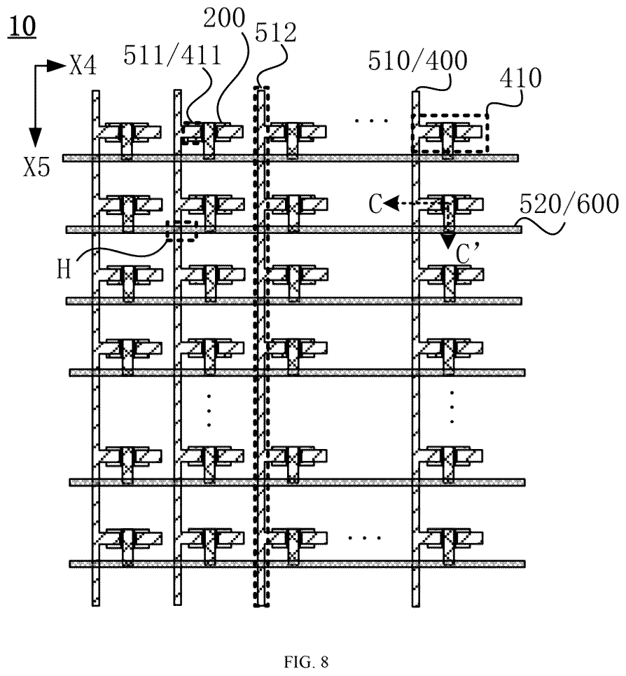

In one embodiment shown in FIG. 7 which is a schematic diagram of the structure of another exemplary display panel, FIG. 8 which is a schematic diagram of the structure of another exemplary display panel and FIG. 3, the display panel 10 may also include a plurality of data signal lines 510 and a plurality of scan signal lines 520. The plurality of data signal lines 510 may be arranged along the fourth direction X4 and extend along the fifth direction X5, and the plurality of scan signal lines 520 may be arranged along the fifth direction X5 and extend along the fourth direction X4, where the fourth direction X4 and the fifth direction X5 intersect and are parallel to the plane where the substrate 100 is located. One corresponding data signal line 510 may be electrically connected to the first electrode 411, and one corresponding scan signal line 520 may be electrically connected to the first gate 412. The data signal line 510 or the scan signal line 411 may be located in the first metal layer 400.

The display panel 10 may include the plurality of data signal lines 510 and the plurality of scan signal lines 520. The corresponding scan signal line 520 may be electrically connected to the first gate 412. The control signal in the scan signal lines 520 may be transmitted to the first gate 412, thereby adjusting the transistor 410 to be turned on or off. The corresponding data signal line 510 may be electrically connected to the first electrode 411. The data signal in the data signal lines 510 may be transmitted to the transistor 410 through the first electrode 411.

In one embodiment shown in FIG. 7 which illustrates a partial structural diagram of the display panel 10 and is used to reflect the relative positional relationship between the plurality of data signal lines 510, the plurality of scan signal lines 520 and the plurality of transistors 410. As shown in FIG. 7, the plurality of data signal lines 510 may be arranged along the fourth direction X4 and extend along the fifth direction X5. The plurality of scan signal lines 520 may be arranged along the fifth direction X5 and extend along the fourth direction X4. That is, the extension direction of the plurality of data signal lines 510 may intersect with the extension direction of the plurality of scan signal lines 520. The fourth direction X4 may be understood as the row direction in FIG. 7, and the fifth direction X5 may be understood as the column direction in FIG. 7. It should be noted that the first direction X1, the second direction X2, the third direction X3, the fourth direction X4 and the fifth direction X5 mentioned in the present disclosure may be directions indicated in the corresponding embodiments and the corresponding drawings, and there may be a situation where the directions are the same. For example, the second direction X2 and the third direction X3 in FIG. 3 are the same in this figure.

The first metal layer 400 may include the first electrode 411 and the first gate 412. As shown in FIG. 3, the first metal layer 400 may be located on a side of the first insulating layer 300 away from the substrate 100. One of the corresponding data signal line 510 electrically connected to the first electrode 411 or the corresponding scan signal line 520 electrically connected to the first gate 412 may also be arranged in the first metal layer 400, to reduce the number of film layers occupied by the wiring in the display panel 10, thereby being beneficial to realizing the thin design of the display panel 10. For example, in one embodiment, as shown in FIG. 8, the data signal line 510 may be arranged in the first metal layer 400, that is, the data signal line 510 may be arranged in the same layer as the first electrode 411, which ensures the reliability of the transmission of the electrical signal and may also reduce the number of film layers arranged in the display panel 10 to help realize the thin design of the display panel 10. The preparation process of the display surface 10 may be reduced, saving costs. Optionally, the scan signal line 5200 may also be set in the first metal layer 400, that is, the scan signal line 520 may be set in the same layer as the first gate 412.

The signals transmitted in the scan signal line 520 and the data signal line 510 may be different, and the two cannot be short-circuited. Also, the extension direction of the scan signal line 520 and the data signal line 510 may be different. Along the thickness direction of the display panel 10, that is, along the first direction X1, there may be an overlapping area between the data signal line 510 and the scan signal line 520. To avoid short-circuiting between the scan signal line 520 and the data signal line 510, the scan signal line 520 and the data signal line 510 may be set in different layers to ensure stable transmission of the signal and stable operation of the transistor 410.

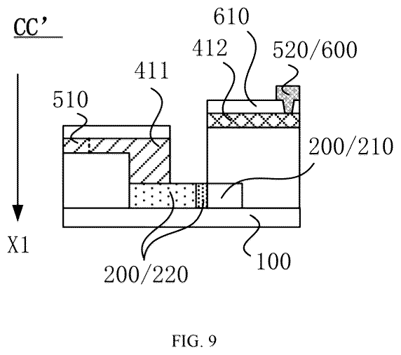

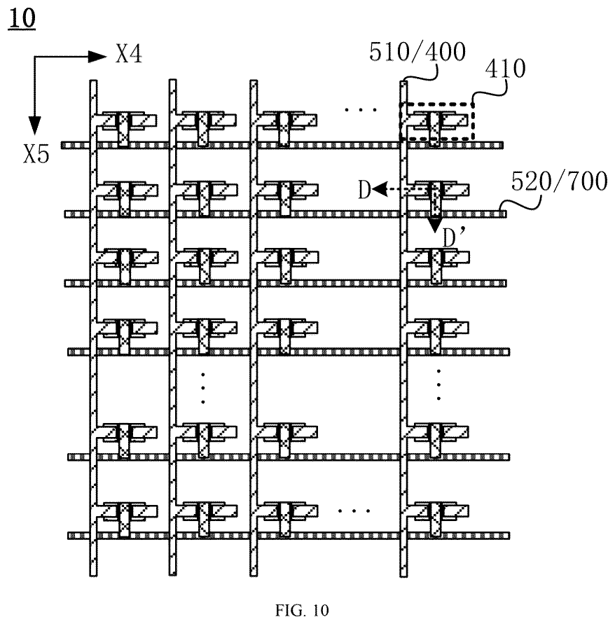

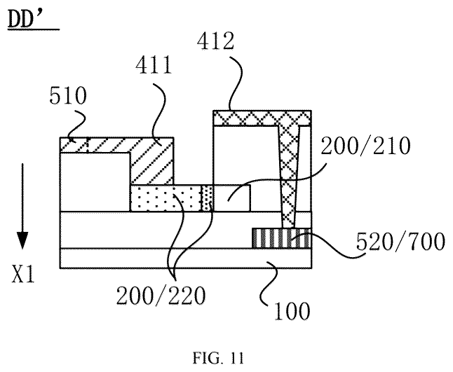

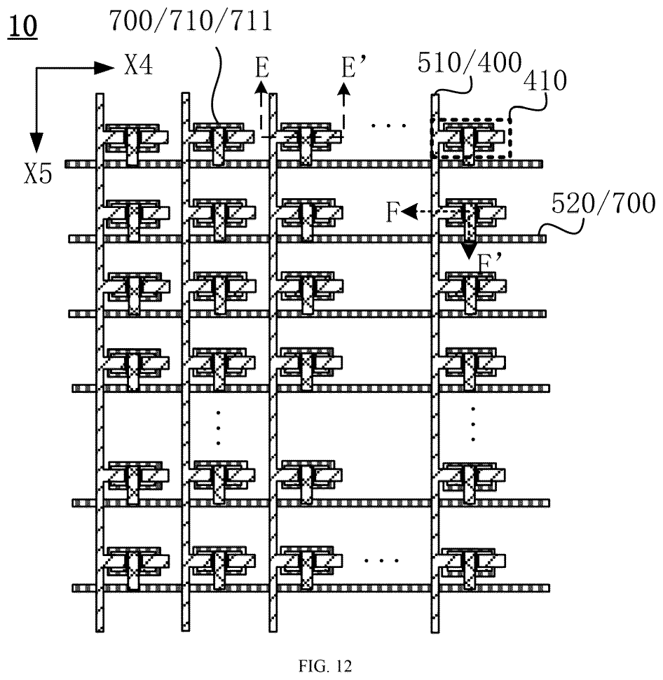

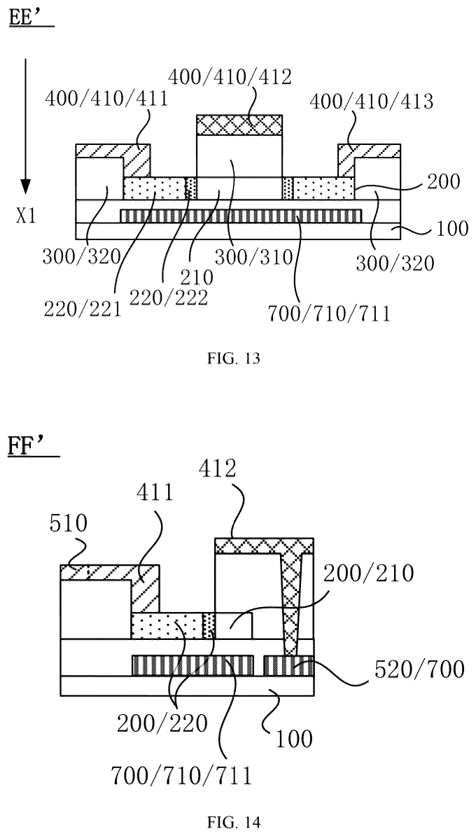

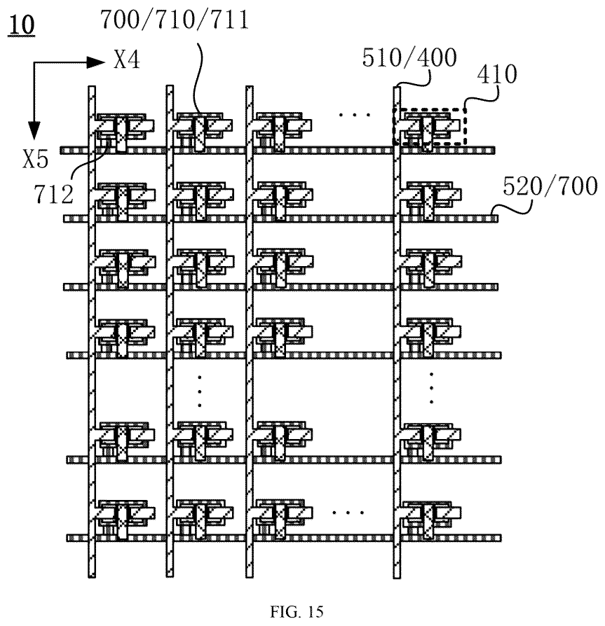

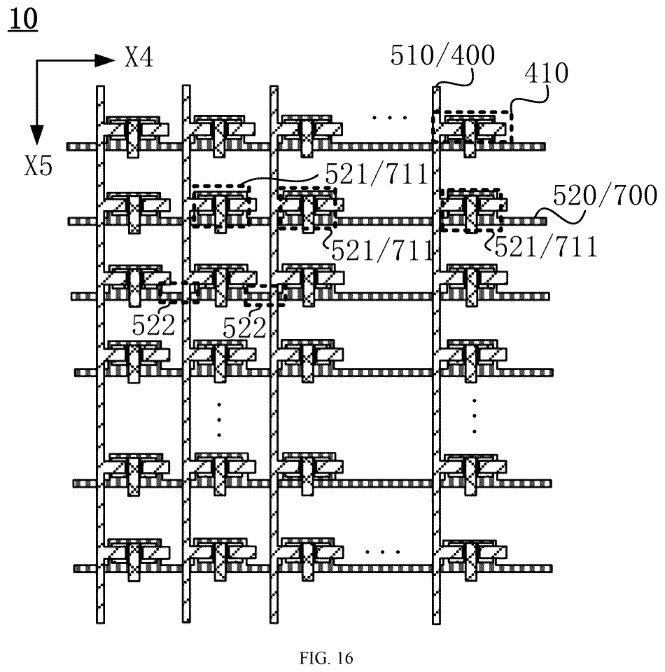

In one embodiment shown in FIG. 9 which is a cross-sectional schematic diagram along the section line C-C′ in FIG. 8, FIG. 10 which is a structural schematic diagram of another display pane, FIG. 11 which is a cross-sectional schematic diagram along the section line D-D′ in FIG. 8, FIG. 12 which is a structural schematic diagram of another display panel, FIG. 13 which is a cross-sectional schematic diagram along the section line E-E′ in FIG. 12, FIG. 14 which is a cross-sectional schematic diagram along the section line F-F′ in FIG. 12, FIG. 15 which is a structural schematic diagram of another display panel, FIG. 16 which is a structural schematic diagram of another display panel, and FIG. 8, the data signal line 510 may be located in the first metal layer 400.

As shown in FIG. 8, FIG. 10, FIG. 12, FIG. 15 and FIG. 16, in one embodiment, the data signal line 510 and the first electrode 411 in the display panel 10 may both be located in the first metal layer 400. As shown in FIG. 9, FIG. 11 and FIG. 14, the data signal line 510 and the first electrode 411 may be located in the same film layer. While ensuring the stability of the electrical connection between the data signal line 510 and the first electrode 411, the number of film layers of the display panel 10 as a whole may be reduced. Therefore, while achieving a thin design, the process preparation cost of the display panel 10 may also be reduced.

When the data signal line 510 is located in the first metal layer 400, to ensure that the signals in the data signal line 510 and the scan signal line 520 are both stably transmitted, the scan signal line 520 may be set in various ways, as shown in FIG. 8, FIG. 10, FIG. 12, FIG. 15 and FIG. 16.

In one embodiment shown in FIG. 8 and FIG. 9, the display panel 10 may further include a second metal layer 600 on a side of the first metal layer 400 away from the substrate 100; and the scan signal line 520 may be located on the second metal layer 600.

For example, as shown in FIG. 8 and FIG. 9, the display panel 10 f may further include a second metal layer 600 on a side of the first metal layer 400 away from the substrate 100. As shown in FIG. 9 which only shows a partial area of the scan signal line 520, along the first direction X1, the second metal layer 600 may be located on the side of the first interlayer insulating layer 610 away from the first metal layer 400, and a first interlayer insulating layer 610 may be provided to ensure stable transmission of signals between the first metal film layer 400 and the second metal film layer 600. Optionally, the first metal layer 400 and the second metal layer 600 may be made of Ti/Al/Ti metal stack or Mo/Al/Mo metal stack, etc., such that the resistance of the first metal layer 400 and the second metal layer 600 may be small and the transmission effect of the electrical signal may be ensured.

As shown in FIG. 8 and FIG. 9, the scan signal line 520 may be disposed in the film layer where the second metal layer 600 is located. The scan signal line 520 located in the second metal layer 600 may be electrically connected to the first gate 412 through a via hole to ensure the transmission of the control signal, thereby ensuring the regulation of the working state of the transistor 410.

In one embodiment shown in FIG. 10 and FIG. 11, the display panel 10 may further include a third metal layer 700, which is located on a side of the first metal layer 400 close to the substrate 100, and the scan signal line 520 may be located on the third metal layer 700.

As shown in FIG. 10 and FIG. 11, the display panel 10 may further include a third metal layer 700, which is located on a side of the first metal layer 400 close to the substrate 100. As shown in FIG. 11 which only shows a partial area of the scan signal line 520, optionally, the material of the first metal layer 400 may be Ti/Al/Ti metal stack or Mo/Al/Mo metal stack, etc., and the material of the third metal layer 700 may be Mo, etc., such that the resistance of the first metal layer 400 and the third metal layer 700 may be small, and the transmission effect of the electrical signal may be ensured.

As shown in FIG. 10 and FIG. 11, the scan signal line 520 may be arranged at the film layer where the third metal layer 700 is located. The first gate 412 may be electrically connected to the scan signal line 520 through a via hole, that is, the scan signal line 520 located in the third metal layer 700 may be connected to the first gate 412 located in the first metal layer 400 through the via hole, thereby ensuring the transmission of the control signal and ensuring the regulation of the working state of the transistor 410.

As shown in FIGS. 12 to 14, the display panel 10 may further include a light shielding structure 710. The light shielding structure 710 may include a first light shielding pattern 711. The first light shielding pattern 711 may at least partially overlap with the active layer 200 along the first direction X1. The light shielding structure 710 may be located in the third metal layer 700.

The display panel 10 may further include the light shielding structure 710 which has the effect of blocking light transmission. The light shielding structure 710 may be located in the third metal layer 700, that is, the light shielding structure 710 may be located on the side of the first metal layer 400 close to the substrate 100. The light shielding layer 710 may include the first light shielding pattern 711. As shown in FIGS. 12 to 14, along the first direction X1, the first light shielding pattern 711 may at least partially overlap with the active layer 200, that is, the first light shielding pattern 711 may be able to block part of the light transmitted to the active layer 200, thereby avoiding the threshold drift of the transistor 410. When the active layer 200 of the transistor 410 is exposed to light, the stability of its operation may be affected. For example, when the transistor 410 is an oxide (Indium Gallium Zinc Oxide, IGZO) transistor, its active layer 200 may be more easily affected by light. The first light shielding pattern 711 may play a role in shielding light, avoiding the threshold drift of the transistor 410, and ensuring the working stability of the transistor 410. When the transistor 410 is a transistor in a pixel circuit, the overall display effect of the display panel 10 may also be ensured.

As shown in FIG. 13, the first light shielding pattern 711 may be located in the third metal layer. In one embodiment, as shown in FIG. 14, the scan signal line 520 and the first light shielding pattern 711 may be both located in the third metal layer 700, such that the number of film layers of the display panel 10 is reduced, which is beneficial to realizing the thin design of the display panel 10 and may also reduce the process preparation cost of the display panel 10.

As shown in FIG. 15, in one embodiment, the light shielding structure 710 may further include a first light shielding extension pattern 712. The first light shielding extension pattern 712 may connect the first light shielding pattern 711 and the scan signal line 520.

As shown in FIG. 15, the light shielding structure 710 may further include the first light shielding extension pattern 712. The light shielding structure 710 may be located in the third metal layer 700, and the corresponding first light shielding extension pattern 712 and the first light shielding pattern 711 may also located in the third metal layer 700. The scan signal line 520 electrically connected to the first gate 412 may also be located in the third metal layer 700.

As shown in FIG. 15, the first light shielding pattern 711 may be electrically connected to the scan signal line 520 through the first light shielding extension pattern 712, and the first light shielding pattern 711 and the first light shielding extension pattern 712 may also transmit the control signal in the scan signal line 520 correspondingly. Along the first direction X1, the first light shielding pattern 711 may at least partially overlap with the active layer 200 (the relative positions of the first light shielding pattern 711 and the active layer 200 along the first direction X1 are shown in FIG. 13), and the first light shielding pattern 711 may be electrically connected to the scan signal line 520 through the first light shielding extension pattern 712, such that the first light shielding pattern 711 is equivalent to the bottom gate of the transistor 410 and is also able to control the on or off of the transistor 410. That is, in the transistor 410, the first gate 412 may be considered as its top gate, and the first light shielding pattern 711 may be considered as its bottom gate. Therefore, the transistor 410 may be a top-bottom dual-gate transistor, improving the working stability and reliability of the transistor 410, and also ensuring the reliability of signal transmission in the display panel 10.

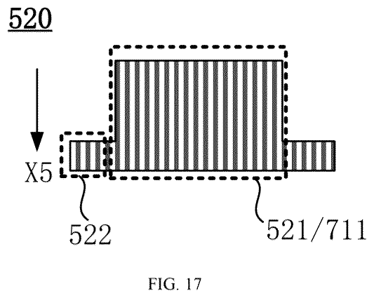

In one embodiment shown in FIG. 16 and FIG. 17 which is a schematic diagram of one scan signal line in FIG. 16, the scan signal line 520 may include a plurality of first sections 521 and a plurality of second sections 522. The plurality of first sections 521 and the plurality of second sections 522 may be sequentially arranged along the fourth direction X4, and two adjacent first sections 521 may be electrically connected through the second sections 522. Along the fifth direction X5, the width of the plurality of first sections 521 may be larger than the width of the plurality of second sections 522. Along the first direction X1, the plurality of first sections 521 may at least partially overlap with the active layer 200, and the plurality of second sections 522 may not overlap with the active layer 200. The plurality of first sections 521 may be multiplexed as the first light shielding pattern 711.

As shown in FIG. 16, the scan signal line 520 extending along the fourth direction X4 may include the plurality of first sections 521 and the plurality of second sections 522. The plurality of first sections 521 and the plurality of second sections 522 may be sequentially arranged along the fourth direction X4. It can be understood that along the fourth direction X4, two adjacent first sections 521 may be electrically connected via one corresponding second section 522, and two adjacent second sections 522 may be electrically connected through one corresponding first section 521. The control signal transmitted by the scan signal line 520 may be transmitted sequentially via one first section 521, one second section 522, and one first section 521.

The first direction X1 may be understood as a direction perpendicular to the plane shown in FIG. 16, or as a direction perpendicular to the plane determined by the fourth direction X4 and the fifth direction X5. Along the first direction X1, the plurality of first section 521 may overlap at least partially with the active layer 200, that is, the plurality of first sections 521 may be located on the side of the active layer 200 close to the substrate 100, and the control signal may be transmitted in the plurality of first sections 521. One first section 521 may be understood as the bottom gate of the corresponding transistor 410. The plurality of second sections 522 may not overlap with the active layer 200 along the first direction X1, and may be equivalent to a connection structure for electrically connecting the plurality of first sections 521 arranged in sequence along the fourth direction X4, that is, ensuring that the plurality of first sections 521 may all obtain relevant control signals. Further, the first gate 412 may be electrically connected to the scan signal line 520, and the first gate 412 may be connected to one corresponding first section 521 through a via hole, such that the transistor 410 is a top-bottom dual-gate transistor, ensuring the working accuracy and stability of the transistor 410. The scan signal line 520 may include the plurality of first sections 521 and the plurality of second sections 522, and the plurality of first sections 521 and the plurality of second sections 522 may be located in the third metal layer 700. It can be understood that the scan signal line 520 for providing the control signal may be set at the third metal layer 700, and in the extension path of the scan signal line 520, a part of the area may overlap with the active layer 200 in the first direction X1. While realizing the control of the transistor 410, the corresponding bottom gate structure (i.e., the corresponding first section 521) may also be added to improve the control effect of the transistor 410 and ensure the working stability of the transistor 410.

Further, as shown in FIG. 17, along the fifth direction X5, the width of the plurality of first sections 521 may be larger than the width of the plurality of second sections 522. One corresponding first section 521 may be used as the bottom gate of the transistor 410, and the plurality of second sections 522 may have a portion overlapping with the data signal line 510. By reducing the width of the plurality of second sections 522, the parasitic capacitance between the scan signal line 520 and the data signal line 510 may be reduced.

Along the first direction X1, the plurality of first section 521 in the scan signal line 520 may at least partially overlap with the active layer 200, and the first plurality of section 521 may be multiplexed as the first light shielding pattern 711. Therefore, the number of film layers set in the display panel 10 may be also reduced, which is beneficial to realizing the thin design of the display panel 10 and reducing the process preparation cost of the display panel 10.

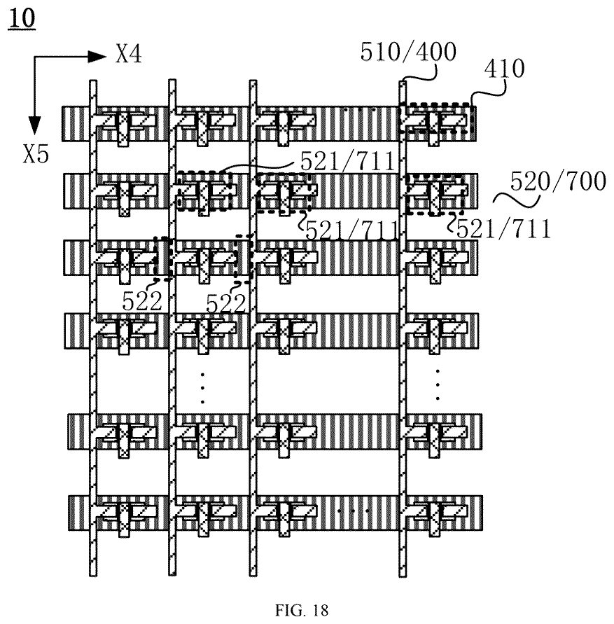

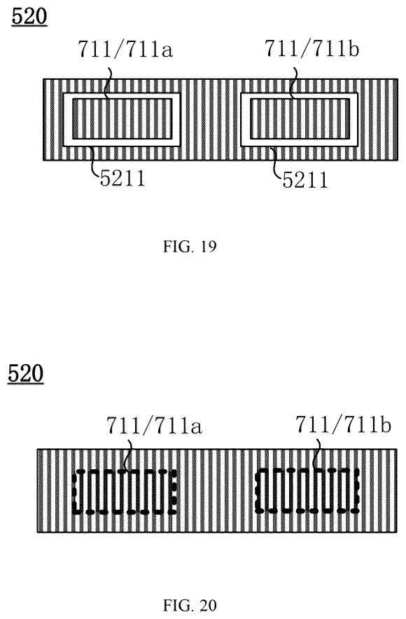

In one embodiment shown in FIG. 18 which is a schematic diagram of another display panel, FIG. 19 which is a scan signal line in FIG. 18, and FIG. 20 which is a schematic diagram of another scan signal line in FIG. 18, the scan signal line 520 may include a plurality of hollow units 5211, and the first light shielding pattern 711 may be disposed in the plurality of hollow units 5211.

As shown in FIG. 18, the line width of the scan signal line 520 may be increased to reduce the resistance of the scan signal line 520, thereby ensuring the effect of signal transmission on the scan signal line 520.

As shown in FIG. 18 to FIG. 20, the line width of the scan signal line 520 may be increased to reduce the resistance on the scan signal line 520, thereby ensuring the reliability and stability of signal transmission in the scan signal line 520. Further, the scan signal line 520 with increased line width may at least partially overlap with the transistor 410 along the first direction X1.

As shown in FIG. 18 and FIG. 19, the scan signal line 520 may be arranged in the same layer as the light shielding structure 710 to reduce the overall film thickness of the display panel 10. The scan signal line 520 may also include the plurality of hollow units 5211, and the scan signal line 520 with a larger width may at least partially overlap with the active layer 200. Along the first direction X1, the first light shielding pattern 711 may also at least partially overlap with the active layer 200. Therefore, the first light shielding pattern 711 may be arranged in the plurality of hollow unit 5211, ensuring that the scan signal line 520 has a larger line width. The first light shielding pattern 711 and the scan signal line 520 may also be arranged in the same layer to reduce the overall film thickness of the display panel 10. Exemplarily, in one embodiment as shown in FIG. 19, where only part of the scan signal line 520 is shown and two hollow units 5211 are used as an example for explanation, the first light shielding pattern 711a and the first light shielding pattern 711b may be respectively disposed in the two hollow units 5211, where the first light shielding pattern 711a and the first light shielding pattern 711b correspond to the active layers 200 of different transistors 410 respectively.

As shown in FIG. 18 and FIG. 20, the scan signal line 520 may be arranged in the same layer as the light shielding structure 710 to reduce the overall film thickness of the display panel 10. The scan signal line 520 with a larger width may at least partially overlap with the active layer 200, and, along the first direction X1, the first light shielding pattern 711 may also at least partially overlap with the active layer 200. The scan signal line 520 as a metal wiring may also block the transmitted light. Therefore, part of the scan signal line 520 corresponding to the active layer 200 may be multiplexed as the first light shielding pattern 711, which may also reduce the process preparation process of the display panel 10 and reduce the overall film thickness of the display panel 10. Exemplarily, as shown in FIG. 20 which only shows part of the scan signal line 520 and takes two first light shielding patterns 711 as an example for explanation, the first light shielding pattern 711a and the first light shielding pattern 711b shown correspond to the active layer 200 of different transistors 410, respectively. The first light shielding pattern 711a and the first light shielding pattern 711b in FIG. 20 may be part of the structure of the scan signal line 520.

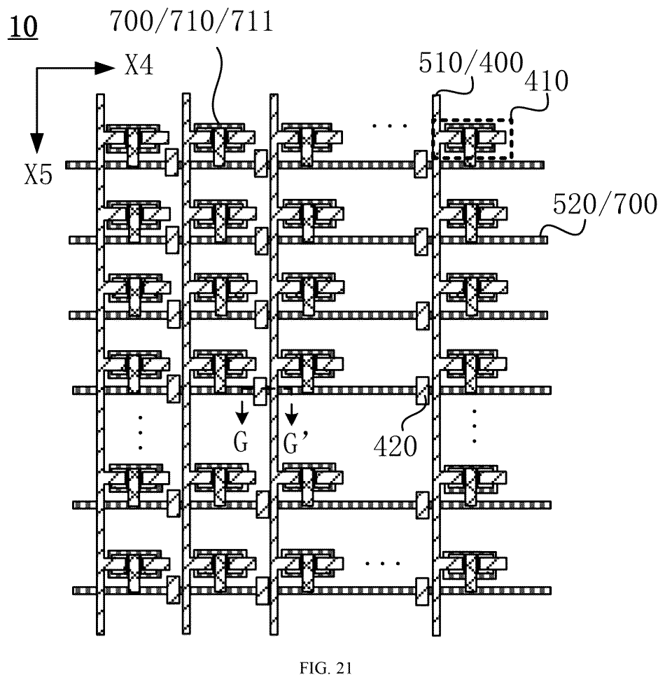

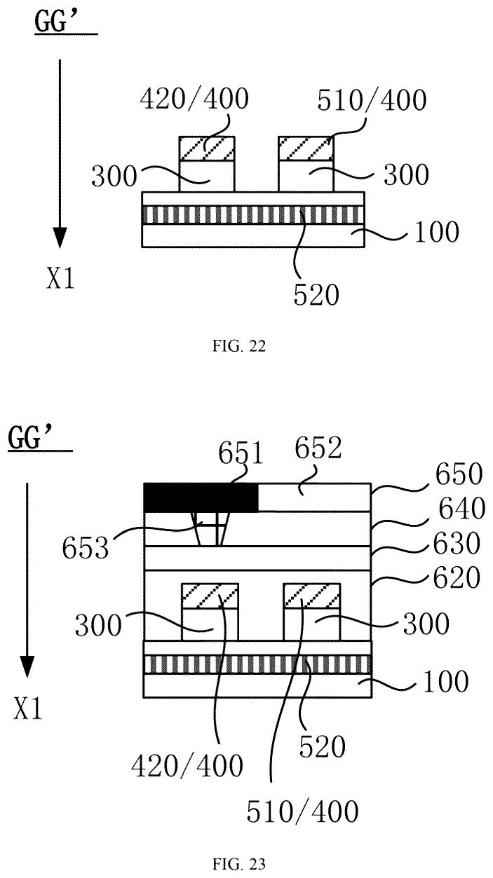

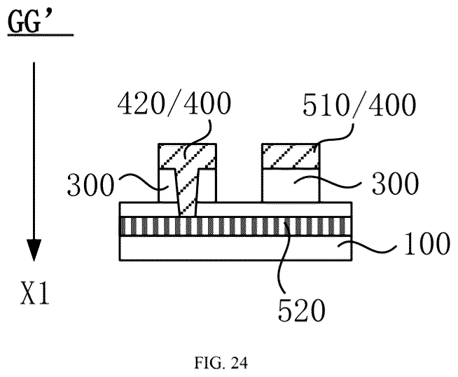

In one embodiment shown in FIG. 21 which is a schematic diagram of another display panel, FIG. 22 which is a cross-sectional schematic diagram along the section line G-G′ in FIG. 21, FIG. 23 which is another cross-sectional schematic diagram along the section line G-G′ in FIG. 21, and FIG. 24 which is another cross-sectional schematic diagram along the section line G-G′ in FIG. 21, the first metal layer 400 may further include a plurality of metal blocks 420.

Along the fourth direction X4, one metal blocks 420 are located between two adjacent data signal lines 510. Along the first direction X1, one metal block 420 may overlap with one corresponding scan signal line 520.

For example, as shown in FIG. 21 and FIG. 22, the first metal layer 400 may further include a plurality of metal blocks 420. Along the fourth direction X4, one metal blocks 420 are located between two adjacent data signal lines 510. FIG. 21 only shows the approximate locations of the plurality of metal blocks 420, and does not specifically limit the specific sizes and shapes of the plurality of metal blocks 420. Further, the plurality of metal blocks 420 may play a positioning effect during the preparation process of the display panel 10 or be used to improve the structural stability of the display panel 10. Exemplarily, in one embodiment shown in FIG. 22, the display panel 10 may be a liquid crystal display panel for example, and the display panel 10 may further include a planarization layer 620, a second interlayer insulating layer 630, a liquid crystal layer 640 and a color film substrate 650. The color film substrate 650 may further include a black matrix 651, a color resist 652 and a support unit 653. Along the first direction X1, the plurality of metal blocks 420 and the support unit 653 may at least partially overlap, that is, the plurality of metal block 420 may be used as position marks to facilitate the preparation of the support unit 653. Further the plurality of metal blocks 420 may also be used as a structure arranged opposite to the support unit 653 on the color film substrate 650, that is, as pads against the support unit 653, to ensure the overall structural stability of the display panel 10.

As shown in FIG. 21 to FIG. 24, along the first direction X1, the metal block 420 may overlap with the corresponding scan signal line 520. As shown in FIG. 24, when the metal block 420 is electrically connected to the corresponding scan signal line 520 through a via, the metal block 420 may be equivalent to being electrically connected in parallel to the corresponding scan signal line 520, thereby reducing the resistance of the scan signal line 520, ensuring the reliability and stability of signal transmission on the scan signal line 520, and ensuring the working stability and reliability of the transistor 410.

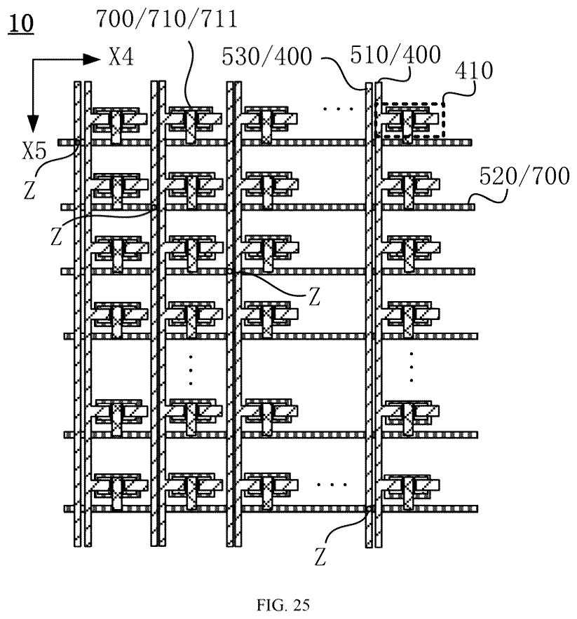

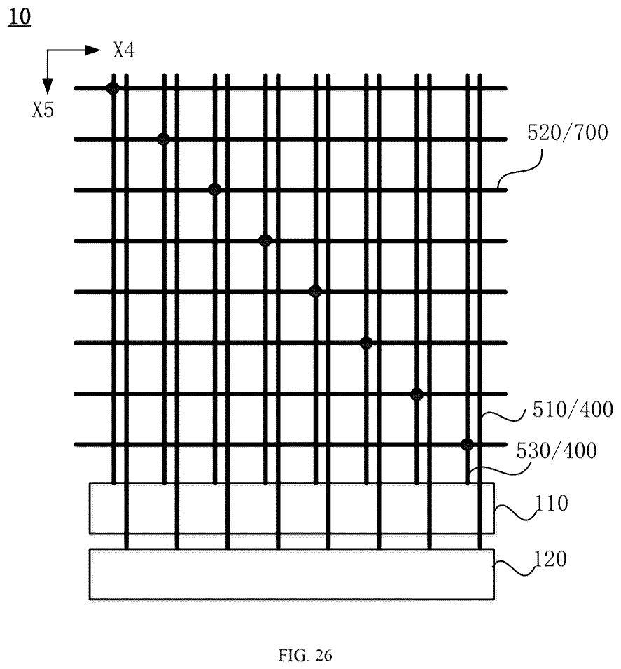

In one embodiment shown in FIG. 25 illustrating another display panel and FIG. 26 illustrating another display panel, the display panel 10 may further include a plurality of scan connection lines 530, and one scan connection line 530 may be electrically connected to one corresponding scan signal line 520. The plurality of scan connection lines 530 may be located in the first metal layer 400 and extend along the fifth direction X5.

As shown in FIG. 25, the display panel 10 may further include the plurality of scan connection lines 530, and the plurality of scan connection lines 530 and the plurality of data signal lines 510 may be located in the first metal layer 400, and the plurality of scan connection lines 530 and the plurality of data signal lines 510 may be extended along the fifth direction X5. The plurality of scan connection lines 530 may be arranged along the fourth direction X4. Further, as shown in FIG. 25, the plurality of scan connection lines 530 and the plurality of scan signal lines 520 may have different extension directions, and may be located in different film layers, and the electrical connection between the plurality of scan connection lines 530 and the plurality of scan signal lines 520 may be realized through via holes (refer to area Z in FIG. 22).

As shown in FIG. 26 which may be understood as a schematic diagram of the routing direction of the plurality of data signal lines 510, the plurality of scan connection lines 530, and the plurality of scan signal lines 520 in FIG. 25, one data signal line 510 may be electrically connected to one corresponding data driving circuit 120. The corresponding data driving circuit 120 may provide the data signal line 510 with a data signal, and the data signal line 510 then may transmit the data signal to the transistor 410. One scan connection line 530 may be electrically connected to one corresponding scan driving circuit 110, and the scan driving circuit 110 may provide the scan connection line 530 with a control signal, and the scan connection line 530 then may transmit the control signal to the transistor 410 through the scan signal line 520. The plurality of scan connection lines 530 and the plurality of data signal lines 510 may be located in the first metal layer 400, and the plurality of scan connection lines 530 and the plurality of data signal lines 510 may extend along the fifth direction X5. The plurality of scan signal lines 520 may be located in the third metal layer 700 and may extend along the fourth direction X4. One scan connection line 530 may be electrically connected to one corresponding scan signal line 520 through a via hole, such that the input end of the scan signal may be transferred to the lower frame of the display panel 10, that is, the setting position of the scan driving circuit 110 in FIG. 26.

When the data signal line 510 and the scan signal line 520 are located in different layers, the scan signal line 520 may also realize signal transmission through the additional scan connection line 530. In this way, the scan drive circuit 110 may be set on the upper frame or the lower frame of the display panel 10 to reduce the size of the left and right frames. The scan drive circuit 110 may use an integrated circuit (IC) to reflect the flexibility of the wiring setting in the display panel 10. In addition, the scan connection line 530 may be set in the same layer as the data signal line 510, which does not increase the film thickness of the display panel 10 and is beneficial to realize the thin design of the display panel 10.

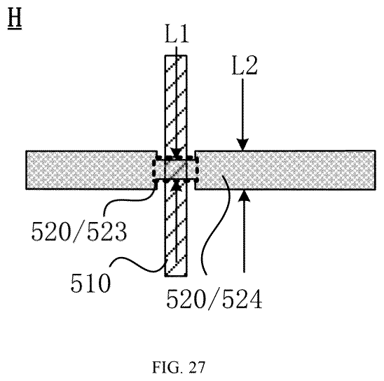

As shown in FIG. 8 and FIG. 27 which is a schematic diagram of a structure of the H region in FIG. 8, the scan signal line 520 may include a third section 523 and a fourth section 524. Along the first direction X1, the third section 523 may at least partially overlap with the data signal line 510, and the fourth section 524 may not overlap with the data signal line 510. The line width of the third section 523 may be smaller than or equal to the line width of the fourth section 524.

As shown in FIG. 8, the scan signal line 520 may extend along the fourth direction X4, and the data signal line 510 may extend along the fifth direction X5. In the first direction X1, part of the scan signal line 520 may overlap with the data signal line 510. To avoid a large parasitic capacitance between the scan signal line 520 and the data signal line 510, the line width of the scan signal line 520 may be adjusted to ensure that the signal transmitted in the scan signal line 520 and the signal transmitted in the data signal line 510 are both stable.

As shown in FIG. 27, the scan signal line 520 may include the third section 523 and the fourth section 524. The third section 523 may be understood as a partial area where the scan signal line 520 overlaps with the data signal line 510 along the first direction X1, and the fourth section 524 may be understood as a partial area where the scan signal line 520 does not overlap with the data signal line 510 along the first direction X1. Further, the scan signal line 520 may be prone to generate parasitic capacitance with the data signal line 510 in the third section 523. The line width of the third section 523 may be reduced and adjusted to reduce the routing area where the parasitic capacitance is generated. As shown in FIG. 27, the line width of the third section 523 may be L1, and the line width of the fourth section 524 may be L2, where L1 is adjusted to be smaller than L2. In general, by reducing the line width of the third section 523 to avoid generating a large parasitic capacitance, while ensuring the line width of the fourth section 524, the overall resistance of the scan signal line 520 may be prevented from being too large, thereby ensuring the stability and reliability of signal transmission in the scan signal line 520 and the data signal line 510.

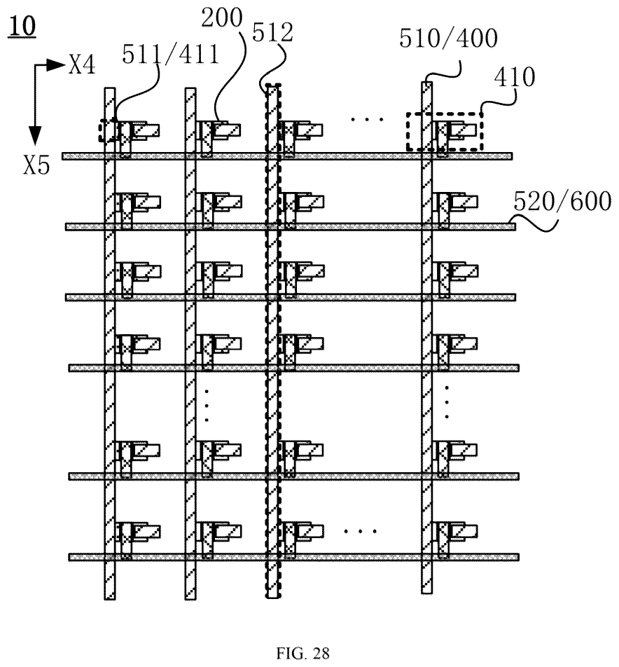

As shown in FIG. 8 and FIG. 28 illustrating another display panel, in one embodiment, the data signal line 510 may include a fifth section 511 and a sixth section 512. Along the first direction X1, the fifth section 511 may at least partially overlap with the active layer 200, and the sixth section 512 may not overlap with the active layer 200. The fifth section 511 may be multiplexed as the first electrode 411.

As shown in FIG. 8 and FIG. 28, the data signal line 510 may include the fifth section 511 and the sixth section 512. Along the first direction X1, the fifth section 511 may at least partially overlap with the active layer 200, and may be disposed in the first metal layer 400 same as the first electrode 411. Therefore, The fifth section 511 may be multiplexed as the first electrode 411. That is, it may be understood as that when the data signal line 510 is in the first metal layer 400, the first electrode 411 is a part of the data signal line 510. At the same time, the sixth section 512 may be understood as the main body extending along the fifth direction X5. Further, the fifth section 511 and the sixth section 512 in FIG. 8 may be two parts of the data signal line 510, and the sixth section 512 in FIG. 28 may include the fifth section 511, and the specific arrangement of the fifth section 511 and the sixth section 512 is flexible.

In above embodiments, the data signal line may be disposed in the first metal layer, and the different arrangements of the scan signal line are described. In some other embodiments, the scan signal line may be disposed in the first metal layer, and the arrangements of the data signal line may be diverse.

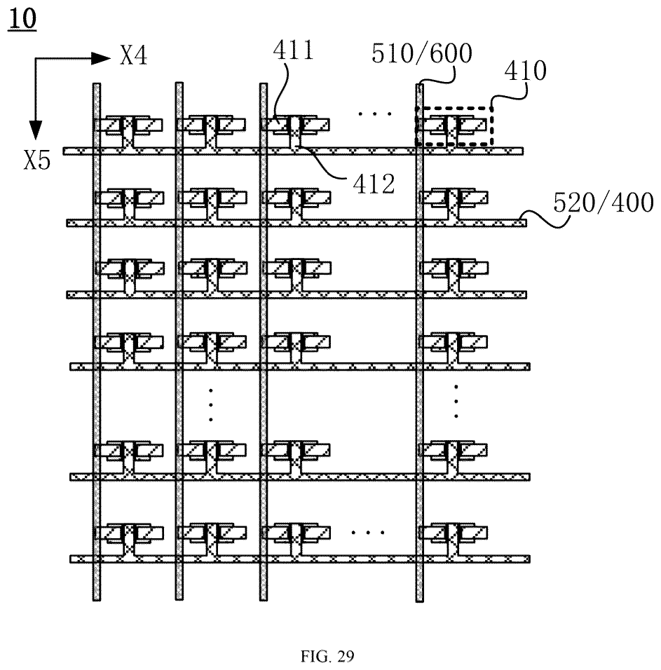

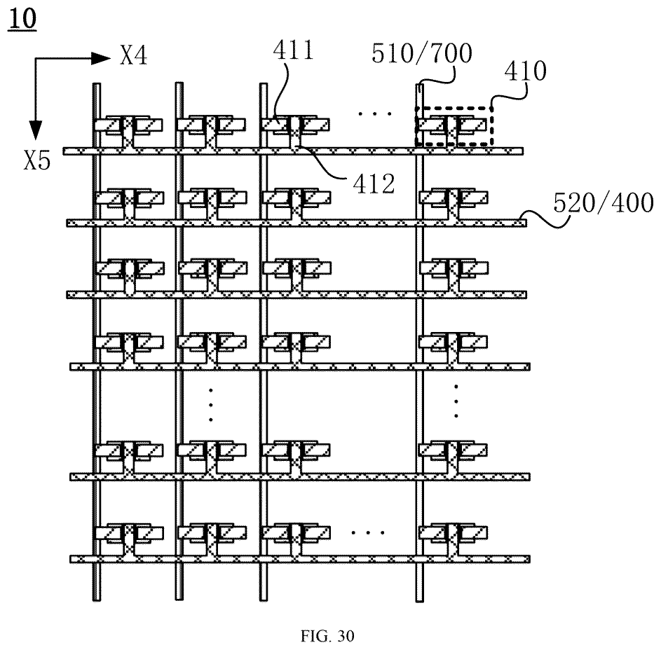

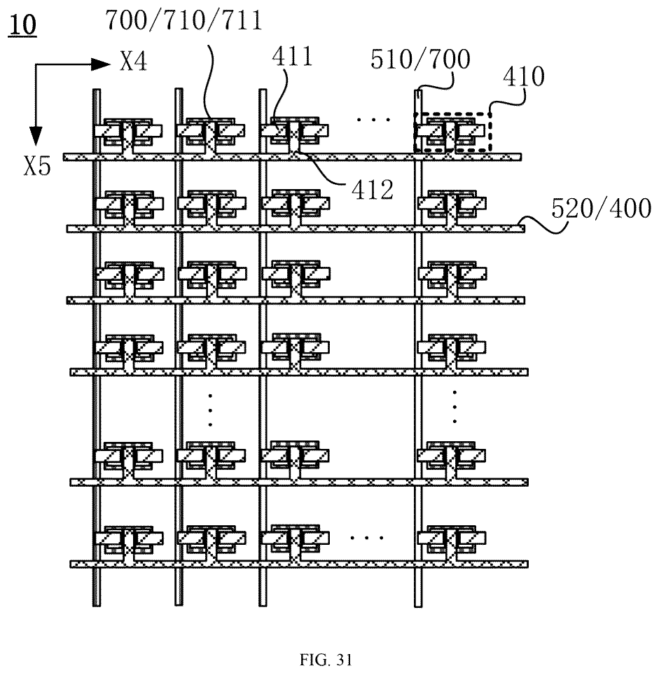

In one embodiment shown in FIG. 29 illustrating another display panel, FIG. 30 illustrating another display panel, and FIG. 31 illustrating another display panel, the scan signal line 520 and the first gate 412 in the display panel 10 may be both located in the first metal layer 400. While ensuring the stability of the electrical connection between the scan signal line 520 and the first gate 412, the number of film layers of the display panel 10 as a whole may be reduced, achieving a thin design and reducing the process preparation cost of the display panel 10. Further, when the scan signal line 520 is located in the first metal layer 400, to ensure that the signals in the data signal line 510 and the scan signal line 520 are both stably transmitted, the data signal line 510 may be arranged in various ways, as shown FIG. 29 to FIG. 31.

In one embodiment shown in FIG. 29, the display panel 10 may further include a second metal layer 600 on a side of the first metal layer 400 away from the substrate 100. The data signal line 510 may be arranged at the film layer where the second metal layer 600 is located. The data signal line 510 located in the second metal layer 600 may be electrically connected to the first electrode 411 through a via hole to ensure the transmission of the control signal, thereby ensuring the regulation of the working state of the transistor 410.

In another embodiment shown in FIG. 30, the display panel 10 may further include a third metal layer 700 on a side of the first metal layer 400 close to the substrate 100. The data signal line 510 may be arranged at the film layer where the third metal layer 700 is located. The first electrode 411 may be electrically connected to the data signal line 510 through a via hole, that is, the data signal line 510 located in the third metal layer 700 may be transmitted to the first electrode 411 located in the first metal layer 400 through the via hole, thereby ensuring the transmission of the control signal and ensuring the regulation of the working state of the transistor 410.

As shown in FIG. 31, the display panel 10 may further include a light shielding structure 710, which has the effect of blocking light transmission. Further, the light shielding structure 710 may be located in the third metal layer 700, that is, the light shielding structure 710 may be located on the side of the first metal layer 400 close to the substrate 100. The light shielding layer 710 may include a first light shielding pattern 711. As shown in FIG. 31, along the first direction X1, the first light shielding pattern 711 may at least partially overlap with the active layer 200, that is, the first light shielding pattern 711 may block part of the light transmitted to the active layer 200, thereby avoiding the threshold drift of the transistor 410.

As shown in FIG. 31, the first light shielding pattern 711 may be located in the third metal layer. The data signal line 510 and the first light shielding pattern 711 may be both located in the third metal layer 700, such that the number of film layers of the display panel 10 may be reduced, which is beneficial to realize the thin design of the display panel 10 to reduce the process preparation cost of the display panel 10. That is, when the scan signal line 520 is located in the first metal layer 400, the setting position and method of the data signal line 510 may be similar to the setting position and method of the scan signal line 520 when the data signal line 510 is located in the first metal layer 400.

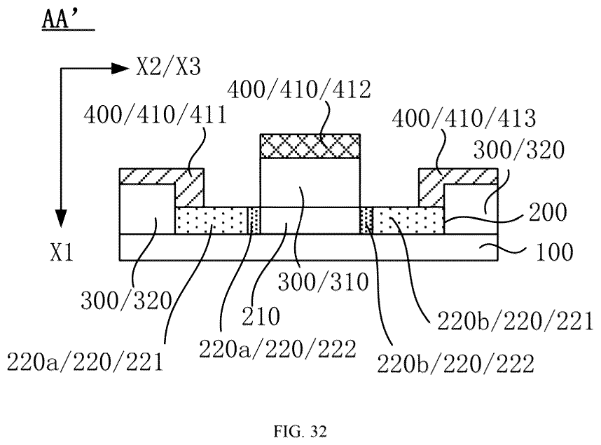

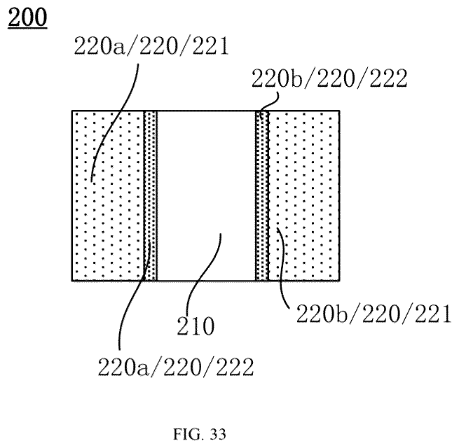

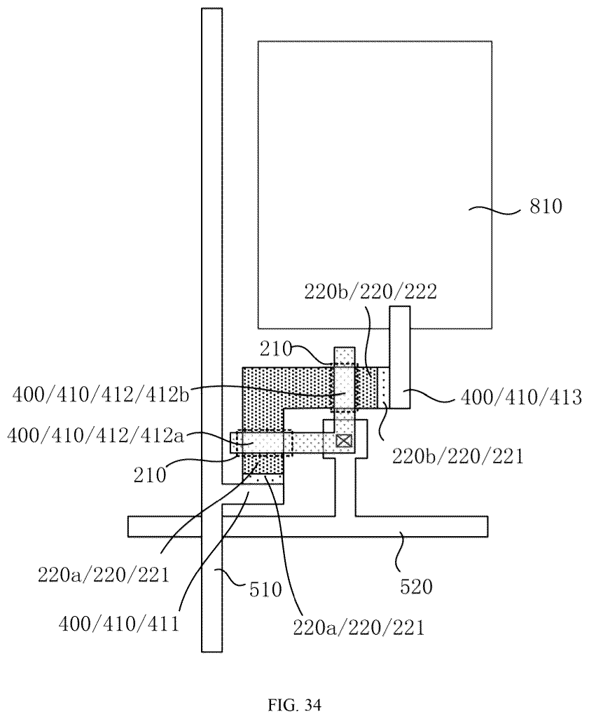

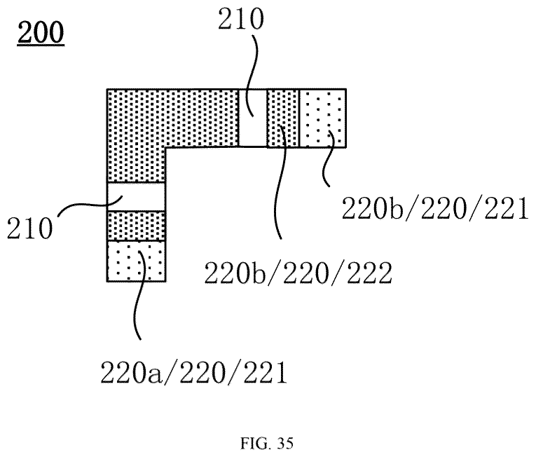

In some embodiments shown in FIG. 1, FIG. 2, FIG. 32 which is another cross-sectional schematic diagram along the section line A-A′ in FIG. 2, FIG. 33 which is a top view of the first active layer, FIG. 34 which is a top view of another transistor, and FIG. 35 is a top view of the first active layer, the doped region 220 may include a first electrode doped region 220a and a second electrode doped region 220b. Along the first direction X1, the first electrode doped region 220a may at least partially overlap with the first electrode 411, and the second electrode doped region 220b may at least partially overlap with the second electrode 413. The first electrode doped region 220a and the second electrode doped region 220b may be located on two sides of the channel region 210.

The transistor 410 may include the first electrode 411 and the second electrode 413, and the first electrode 411 and the second electrode 413 may both be electrically connected to the active layer 200. As shown in FIG. 32 and FIG. 33, the doped region 220 may include the first doped region 220a and the second doped region 220b. The first electrode 411 may be electrically connected to the active layer 200 through the first doped region 220a, and the second electrode 413 may be electrically connected to the active layer 200 through the second doped region 220b. It should be noted that FIG. 32 and FIG. 2 are the same drawings, and to mark the doped region 220 more clearly, the first doped region 220a and the second doped region 220b are shown in FIG. 32.

The first doped region 220a and the second doped region 220b may be flexible in their arrangement positions relative to the channel region 210, which may be understood as that the arrangement positions between the first electrode 411, the second electrode 413 and the first gate 412 are flexible. Exemplarily, in one embodiment, as shown in FIG. 32 and FIG. 33, the first electrode doped region 220a and the second electrode doped region 220b may be located on opposite sides of the channel region 210. In another embodiment shown in FIG. 34 and FIG. 35, the first electrode doped region 220a and the second electrode doped region 220b may be located on adjacent sides of the channel region 210. Further, as shown in FIG. 34 and FIG. 35, the first gate 412 in the transistor 410 may include a first gate section 412a and a second gate section 412b. The first electrode doped region 220a may be located on one side of the first gate section 412a, and the second electrode doped region 220b may be located on one side of the second gate section 412b, where the transistor 410 may be understood as a dual-gate transistor. Further, the transistor 410 shown in FIG. 34 may be a transistor 410 in the liquid crystal display panel 10, and the second electrode 413 may be electrically connected to the pixel electrode 810.

In various embodiments, the first gate 412, the first electrode 411, and the second electrode 413 may have different arrangement positions based on different types of transistors 410. Therefore, the arrangement positions of the channel region 210, the first electrode doped region 220a, and the second electrode doped region 220b in the active layer 200 may be also flexible. FIG. 32 to FIG. 35 only show the arrangement positions of the channel region 210, the first electrode doped region 220a, and the second electrode doped region 220b in a part of the active layer 200, and the embodiments of the present disclosure do not show all embodiments one by one.

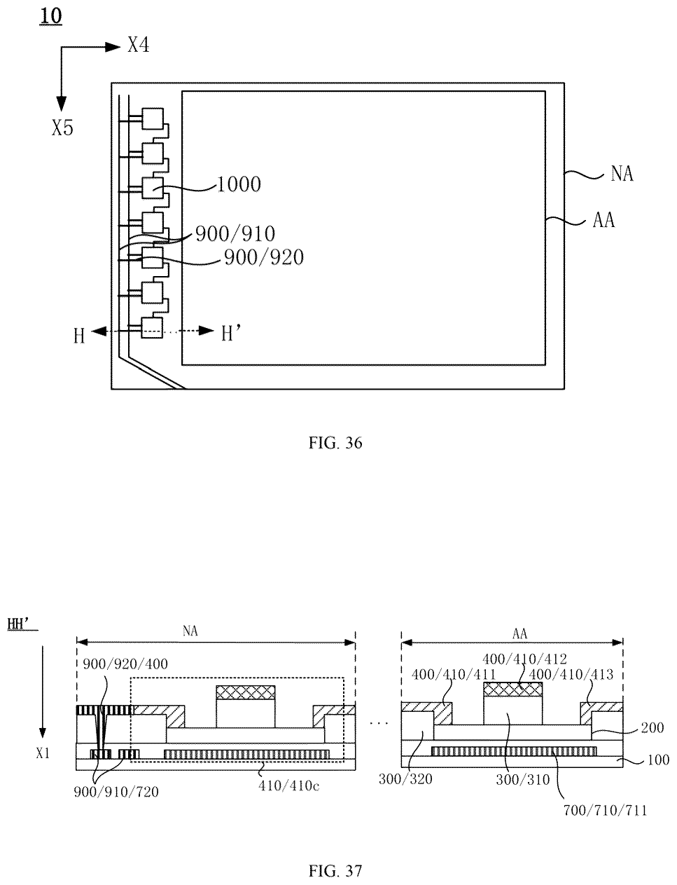

In one embodiment shown in FIG. 36 and FIG. 37, the display panel 10 may include a display area AA and a non-display area NA, and the non-display area NA may be located at least on one side of the display area AA. The display panel 10 may also include a plurality of signal lines 900 located in the non-display area NA. The plurality of signal lines 900 may include a plurality of first signal lines 910 and a plurality of second signal lines 920. The plurality of first signal lines 910 may be arranged along a fourth direction X4 and extend along a fifth direction X5. The plurality of second signal lines 920 may be arranged along the fifth direction X5 and extend along the fourth direction X4. The fourth direction X4 and the fifth direction X5 may intersect, and the fourth direction X4 and the fifth direction X5 may be parallel to the plane where the substrate 100 is located. The plurality of first signal lines 910 or the plurality of second signal lines 920 may be located in the first metal layer 400.

As shown in FIG. 37, the display panel 10 may include the display area AA and the non-display area NA. The display area AA may be used to realize the display function of the display panel 10. The non-display area NA may include a display controller connected to the data signal line 510, such as a driver chip (not specifically shown in the figure), and the display controller may provide a data signal to the data signal line 510, thereby driving the display panel 10 to realize the display function. The non-display area NA may surround at least a portion of the display area AA. Based on the specific positions of the display area AA and the non-display area NA, the embodiments of the present disclosure do not make specific limitations.

As shown in FIG. 36, the display panel 10 may also include a plurality of signal lines 900 located in the non-display area NA. The plurality of signal lines 900 may include a plurality of first signal lines 910 and a plurality of second signal lines 920. The plurality of first signal lines 910 and the plurality of second signal lines 920 may have different extension directions. The plurality of first signal lines 910 may be understood as extending along the column direction, i.e., the fifth direction X5 in FIG. 36, and the plurality of second signal lines 920 may be understood as extending along the row direction, i.e., the fourth direction X4 in FIG. 36.

The extension direction of the plurality of first signal lines 910 may intersect with the extension direction of the plurality of second signal lines 920. To avoid short-circuiting of the plurality of first signal lines 910 and the plurality of second signal lines 920 at non-via locations, the plurality of first signal lines 910 and the plurality of second signal lines 920 may be arranged in different layers.

The display panel 10 may include a first metal layer 400, and the first metal layer 400 may be located on a side of the first insulating layer 300 away from the substrate 100. To reduce the number of film layers in the display panel 10, as shown in FIG. 37, one of the plurality of first signal lines 910 and the plurality of second signal lines 920 may be set in the first metal layer 400, such that the number of film layers occupied by the wiring in the display panel 10 is reduced, which is beneficial to the thin design of the display panel 10. Exemplarily, in one embodiment, as shown in FIG. 37, the plurality of first signal lines 910 and the plurality of second signal lines 920 may be arranged in different layers, and one first signal line 910 may be electrically connected to one corresponding second signal line 920 through a via, and the signal transmitted in the first signal line 910 may be transmitted to the transistor 410c of the driving circuit 1000 located in the non-display area NA through the second signal line 920. FIG. 37 takes the second signal line 920 being arranged in the first metal layer 400 as an example for illustration, and the arrangement method of the first signal line 910 and the second signal line 920 is flexible.

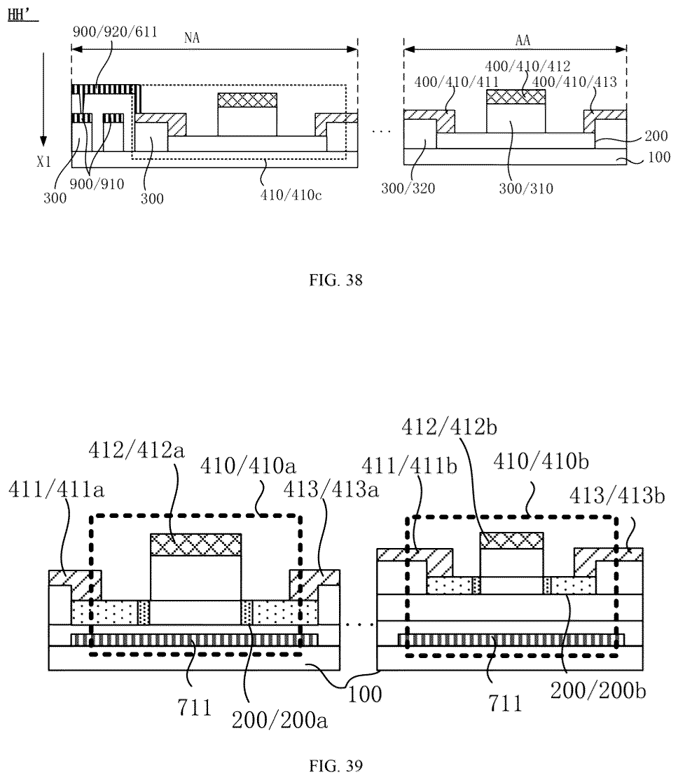

In one embodiment shown in FIG. 36 and FIG. 38 which is another cross-sectional schematic diagram along the section line H-H′ in FIG. 36, the display panel 10 may also include a fourth metal layer 611, and the fourth metal layer 611 may be located on the side of the first metal layer 400 away from the substrate 100. The plurality of first signal lines 910 may be located on the first metal layer 400; and the plurality of second signal lines 920 may be located on the fourth metal layer 611.

As shown in FIG. 38, the display panel 10 may also include a fourth metal layer 611, and the fourth metal layer 611 may be located on the side of the first metal layer 400 away from the substrate 100. As shown in FIG. 9, the position of the film layer of the fourth metal layer 611 may be the same as the position of the film layer of the second metal layer 600.

When the plurality of first signal lines 910 is located in the first metal layer 400, the plurality of second signal lines 920 may be set in the fourth metal layer 611. In another embodiment, the plurality of second signal lines 920 may be set in the first metal layer 400, and the plurality of first signal lines 910 may be set in the fifth metal layer 611. The arrangement of the plurality of first signal lines 910 and the plurality of second signal lines 920 may be adaptively adjusted according to different display panels 10.

As shown in FIG. 36 and FIG. 37, the display panel 10 may also include a fifth metal layer 720 on the side of the first metal layer 400 close to the substrate 100. The plurality of first signal lines 910 may be located in the first metal layer 400; and the plurality of second signal lines 920 may be located in the fifth metal layer 720.

As shown in FIG. 37, the display panel 10 may further include the fifth metal layer 720, and the fifth metal layer 720 may be located on the side of the first metal layer 400 close to the substrate 100. In combination with FIG. 13, the film layer of the fifth metal layer 720 may be set at the same position as the film layer of the third metal layer 700. Further, as shown in FIG. 37, the plurality of first signal lines 910 may be located in the first metal layer 400; and the plurality of second signal lines 920 may be located in the fifth metal layer 720. In another embodiment, the plurality of first signal lines 910 may be located in the fifth metal layer 720; and the plurality of second signal lines 920 may be located in the first metal layer 400. The arrangement of the plurality of first signal lines 910 and the plurality of second signal lines 920 may be adaptively adjusted according to different display panels 10.

As shown in FIG. 36, the display panel 10 may further include a driving circuit 1000 located in the non-display area NA. The plurality of first signal lines 910 may include at least one of a common signal line, a high-level signal line, a low-level signal line, a clock signal line, a reset signal line, a start signal line, or a ground line. The plurality of second signal lines 920 may include a connecting line, and the driving circuit 1000 may be electrically connected to one corresponding first signal line 910 via a corresponding connecting line. The driving circuit 1000 may be a scanning driving circuit, including a plurality of shift registers arranged in cascade which is connected to the scan signal line 520 and used to provide scan signals to the scan signal line 520. The scanning driving circuit may receive the signal provided by the first signal line 910 to form scan signals step by step.

In one embodiment shown in FIG. 2 and FIG. 39 which is a cross-sectional schematic diagram of a transistor, the transistor 410 may include a first transistor 410a and/or a second transistor 410b. The active layer 200a of the first transistor 410a may include a silicon semiconductor portion, and the active layer 200 of the second transistor 410b may include an oxide semiconductor portion.

The transistor 410 may include a first transistor 410a, and the active layer 200a of the first transistor 410a may include a silicon semiconductor portion. The first transistor may be understood as a low temperature polysilicon transistor (LTPS), which has the advantages of high switching speed, high carrier mobility, and low power. The transistor 410 may also include a second transistor 410b, and the active layer 200b of the second transistor 410b may include an oxide semiconductor portion. The second type of transistor may be understood as an oxide (Indium Gallium Zinc Oxide, IGZO) transistor which has the advantages of low leakage current.

As shown in FIG. 39, in one embodiment, the display panel 10 may include a first transistor 410a and a second transistor 410b at the same time. In the first transistor 410a, the first electrode 411a, the first gate 412a and the second electrode 413a may be arranged in the same layer. In the second transistor 410b, the first electrode 411b, the first gate 412b and the second electrode 413b may be arranged in the same layer. When the display panel 10 includes the first transistor 41a and the second transistor 410b, it may have the advantages of high switching speed, high carrier mobility, low power and low leakage current.

In some other embodiments shown in FIG. 2, the display panel 10 may only include one type of transistors. For example, in one embodiment, the active layer 200 in FIG. 2 may be a silicon semiconductor portion, and the display panel 10 may only include the first transistor 410a. In another embodiment, the active layer 200 in FIG. 2 may be an oxide semiconductor portion, and the display panel may only include the second transistor 410b.

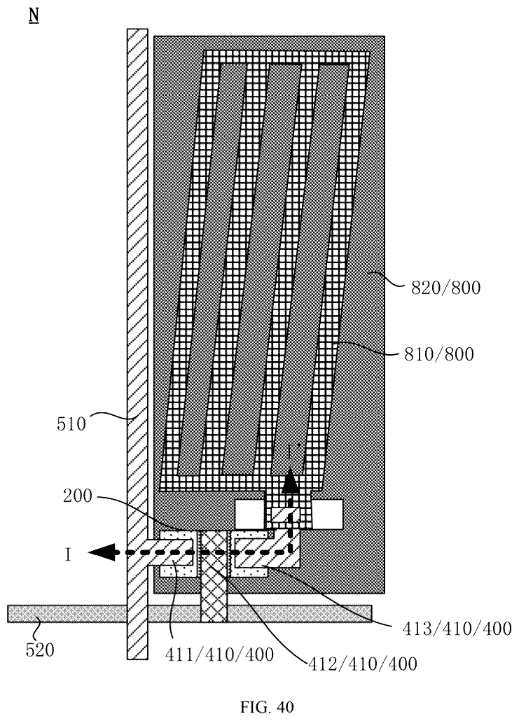

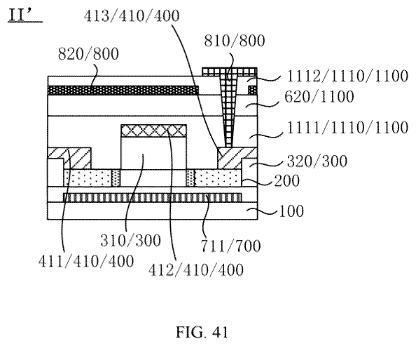

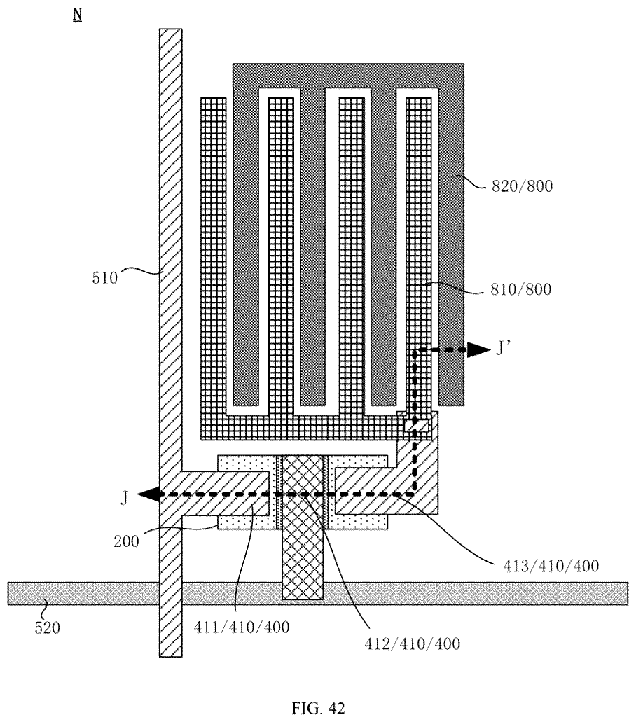

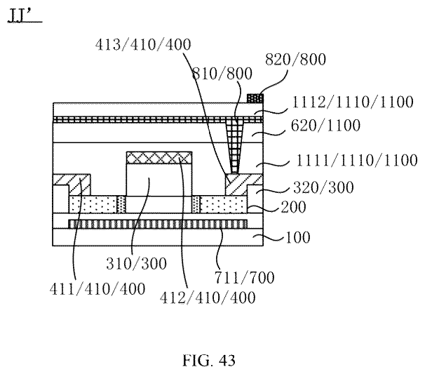

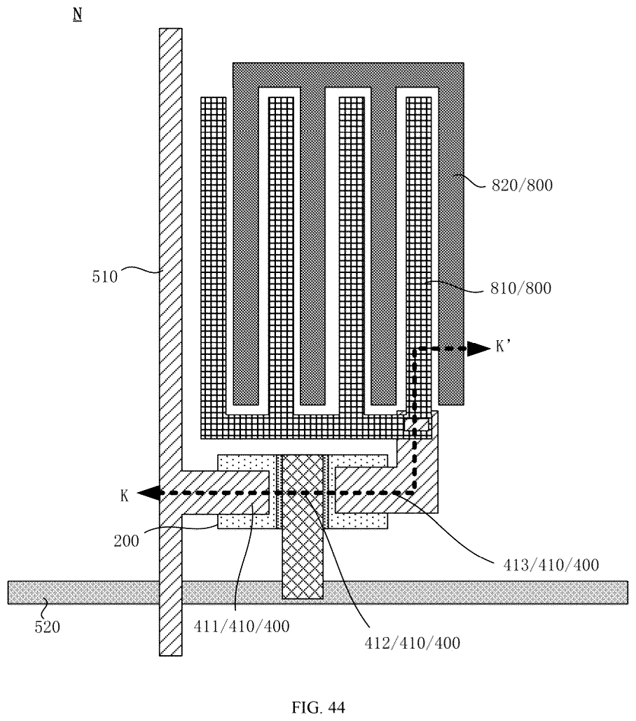

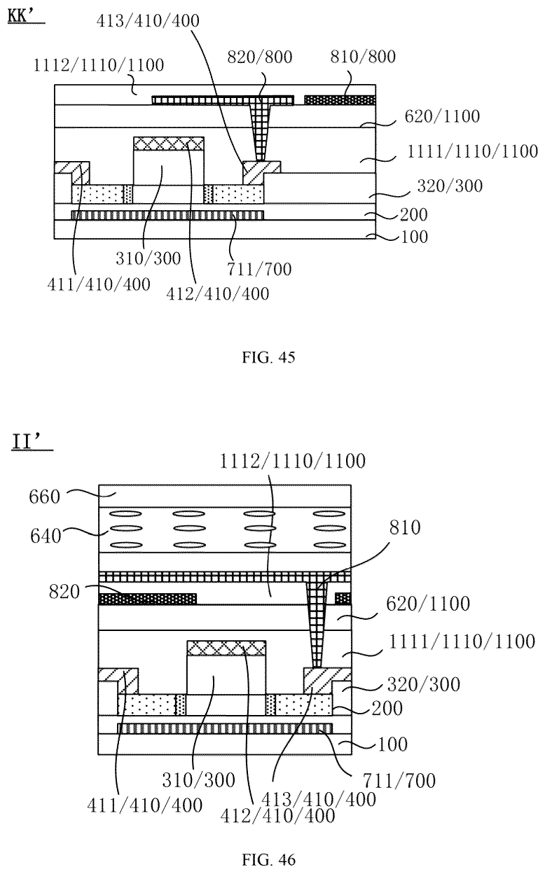

In one embodiment shown in FIG. 8, FIG. 40 which is an enlarged schematic diagram of the region H in FIG. 8, FIG. 41 which is a cross-sectional schematic diagram along section line I-I′ in FIG. 40, FIG. 42 which is another enlarged schematic diagram of the region H in FIG. 8, FIG. 43 which is a cross-sectional schematic diagram along section line J-J′ in FIG. 42, FIG. 44 which is another enlarged schematic diagram of the region H in FIG. 8, and FIG. 45 which is a cross-sectional schematic diagram along section line K-K′ in FIG. 44, the display panel 10 may further include an insulating layer 1100 and an electrode layer 800. The insulating layer 1100 may include a planarization layer 620 and a passivation layer 1110. The planarization layer 620 may be located on a side of the first metal layer 400 away from the substrate 100, and the electrode layer 800 may be located on a side of the planarization layer 620 away from the substrate 100. The electrode layer 800 may include a pixel electrode 810 and a common electrode 820. The pixel electrode 810 may be electrically connected to the second electrode 820. The passivation layer 1110 may include a first passivation layer 1111 and a second passivation layer 1112. The first passivation layer 1111 may be located on a side of the planarization layer 620 close to the first metal layer 400, and the second passivation layer 1112 may be located between the pixel electrode 810 and the common electrode 820.

As shown in FIG. 40 to FIG. 45, the display panel 10 may include the insulating layer 1100. In the insulating layer 1100, the planarization layer 620 may be located on a side of the first passivation layer 1111 away from the substrate 100, and the planarization layer 620 may ensure that the entire film layer of the display panel 10 has flatness. Furthermore, the display panel may further include the electrode layer 800, and the electrode layer 800 may be located on a side of the planarization layer 620 away from the substrate 100.

As shown in FIG. 40 to FIG. 45, the electrode layer 800 may include a pixel electrode 810 and a common electrode 820, and the pixel electrode 810 may be electrically connected to the second electrode 413 of the transistor 410. The pixel electrode 810 and the common electrode 820 may be insulated. Further, in different display panels 10, the relative arrangement positions between the pixel electrode 810 and the common electrode 820 may be diverse. For example, as shown in FIG. 40 and FIG. 41, in one embodiment, the film layer where the pixel electrode 810 is located may be located on the side of the film layer where the common electrode 820 is located away from the substrate 100. Along the first direction X1, the second passivation layer 1112 may be located between the pixel electrode 810 and the common electrode 820, to avoid short circuit between the pixel electrode 810 and the common electrode 820. Exemplarily, as shown in FIG. 42 and FIG. 43, in one embodiment, the film layer where the pixel electrode 810 is located may be located on the side of the film layer where the common electrode 820 is located close to the substrate 100, and along the first direction X1, the second passivation layer 1112 may be located between the pixel electrode 810 and the common electrode 820, for preventing the pixel electrode 810 and the common electrode 820 from shorting. Exemplarily, as shown in FIG. 44 and FIG. 45, in one embodiment, the film layer where the pixel electrode 810 is located may be arranged in the same layer as the film layer where the common electrode 820 is located, and the second passivation layer 1112 may be located between the pixel electrode 810 and the common electrode 820 along the direction of the plane where the substrate 100 may be located, for preventing the pixel electrode 810 and the common electrode 820 from shorting. It should be noted that, the pixel electrode 810 and the common electrode 820 may be arranged in different layers in the embodiment shown in FIG. 43, and the pixel electrode 810 and the common electrode 820 may be arranged in the same layer in the embodiment shown in FIG. 44. Further, as shown in FIG. 44, when the pixel electrode 810 and the common electrode 820 may be arranged in the same layer, both the pixel electrode 810 and the common electrode 820 may be comb-shaped, and the comb teeth may be opposite and cross-arranged to form a horizontal electric field.

In one embodiment, the display panel 10 may be a liquid crystal display panel, and may further include a liquid crystal layer (not specifically shown in the figure). The liquid crystal layer may include a plurality of liquid crystal molecules, which may be deflected under the action of the voltage signal in the pixel electrode 810 and the voltage signal in the common electrode 820, and transmit the light provided by the backlight module (not shown in the figure), thereby realizing the display effect of the liquid crystal display panel. Further, the liquid crystal display panel provided by one embodiment of the present disclosure may be a twisted nematic liquid crystal display panel, in which the pixel electrode 810 and the common electrode 820 may be arranged on two sides of the liquid crystal layer that may be relatively arranged, and the liquid crystal molecules may be used to deflect vertically under the action of the voltage signal in the pixel electrode 810 and the voltage signal in the common electrode 820. Alternatively, the liquid crystal display panel provided by another embodiment of the present disclosure may be a planar control mode display panel, in which the pixel electrode 810 and the common electrode 820 may be arranged on the same side of the liquid crystal layer, and the liquid crystal molecules may be used to deflect in plane under the action of the voltage signal in the pixel electrode 810 and the voltage signal in the common electrode 820. Furthermore, the planar control mode display panel may include a Fringe Field Switching (FFS) display panel or an In-Plane Switching (IPS) display panel. The embodiments of the present disclosure do not limit the specific type of the liquid crystal display panel. The subsequent embodiments will be described by taking the liquid crystal display panel as a planar control mode display panel as an example. Furthermore, for different display panels 10, the number and type of the insulating layer 1100 may be adaptively adjusted, and the embodiments of the present disclosure will not be described in detail one by one.

In one embodiment shown in FIG. 46 which is another cross-sectional schematic diagram along the section line I-I′ in FIG. 40, the display panel 10 may be a liquid crystal display panel; and the liquid crystal display panel may further include a liquid crystal layer 640 and a counter substrate 660. The liquid crystal layer 640 may be located on the side of the first metal layer 400 away from the substrate 100, and the counter substrate 660 may be located on the side of the liquid crystal layer 640 away from the substrate 100.

The display panel 10 may be a liquid crystal display panel, as shown in FIG. 46, and the liquid crystal display panel may further include a liquid crystal layer 640. The liquid crystal layer 640 may be located on the side of the first metal layer 400 away from the substrate, and FIG. 46 shows that both the common electrode 820 and the pixel electrode 810 are located on the side of the liquid crystal layer 640 close to the substrate 100. The common electrode 820 and the pixel electrode 810 may also be located on two sides of the liquid crystal layer 640, respectively, and this is not specifically limited in the present disclosure. Further, the liquid crystal display panel may also include a counter substrate 660, and the counter substrate 660 may be located on a layer of the liquid crystal layer 660 away from the substrate 100. Optionally, the counter substrate 660 may further include a color filter substrate, a polarizer, an insulating layer, and an alignment layer, etc. The specific film layers included in the counter substrate 660 are not specifically limited in the embodiments of the present disclosure.

Optionally, the display panel 10 may also be an organic light-emitting display panel (OLED) or an inorganic light-emitting diode display panel (LED), that is, the display panel 10 may have various types.

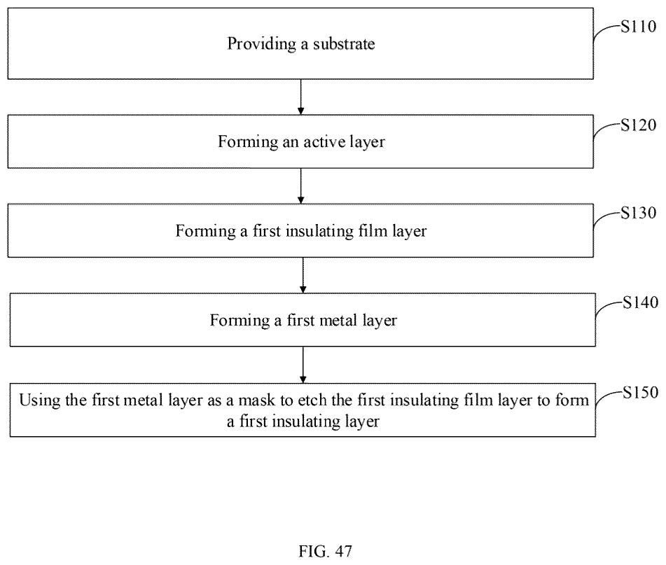

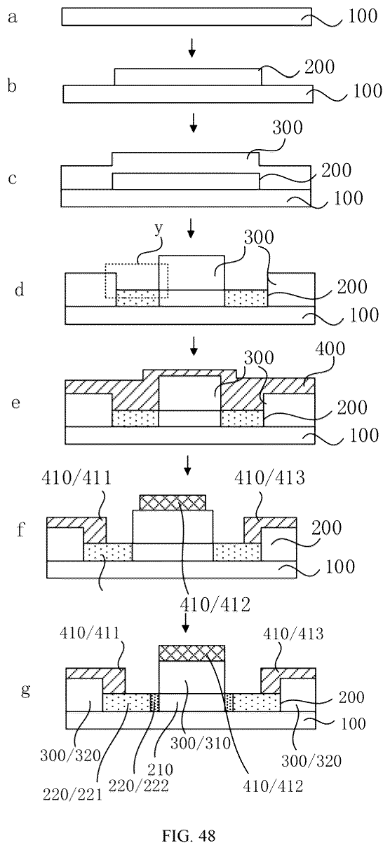

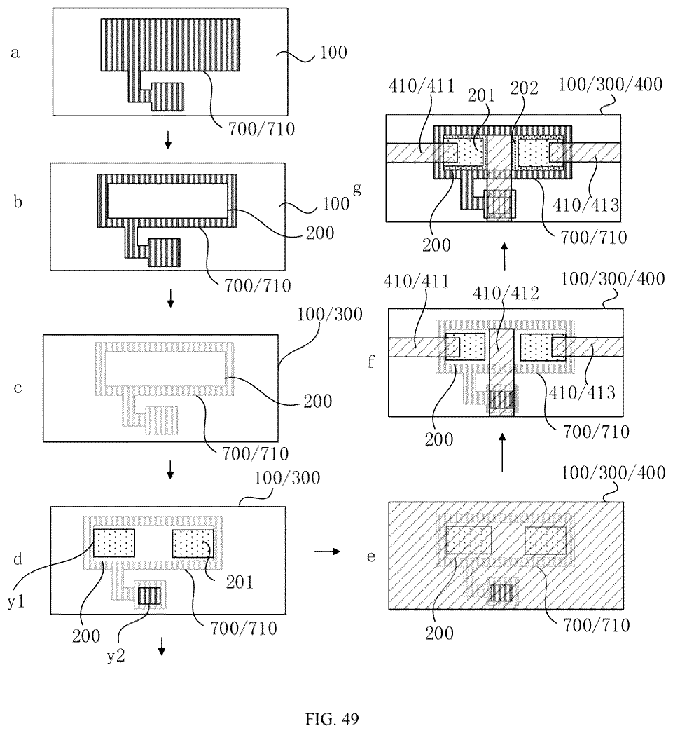

The present disclosure also provides a fabrication method of a display panel. As shown in FIG. 47 which is a flowchart of an exemplary fabrication method of a display panel, FIG. 48 illustrating cross-sectional views of display panels corresponding to various stages of the fabrication method, and FIG. 49 illustrating top views of display panels corresponding to various stages of the fabrication method, in one embodiment, the method may include S110 to S150.

In S110, a substrate 100 may be provided, as shown in step a in FIG. 48 and step a in FIG. 49.

Exemplarily, the provided substrate may be a rigid substrate, such as glass, or a flexible substrate, and the embodiments of the present disclosure do not limit the type of substrate. Further, a film layer of a metal layer and an insulating layer may be subsequently prepared on one side of the substrate.

In S120, an active layer 200 may be formed, as shown in step b in FIG. 48 and step b in FIG. 49.

The active layer 200 may be located on one side of the substrate 100. The display panel may include a transistor, and the active layer may be a film layer structure in the transistor. The active layer in the transistor may be electrically connected to the first electrode and the second electrode in the transistor.

In S130, a first insulating film layer 300 may be formed, as shown in step c in FIG. 48 and step c in FIG. 49.

The first insulating film layer 300 may be located on a layer of the active layer 200 away from the substrate 100, that is, the first insulating film layer may cover the active layer.

Optionally, as shown in step d in FIG. 48 and step d in FIG. 49, the first insulating film layer may be preliminarily etched to form an opening on the first insulating film layer, where the opening y/y1 exposes at least a portion of the active layer. The active layer 200 may be first conductorized through the opening y/y1, i.e., first ion doping may be performed so that the active layer includes a source region and a drain region respectively contacting the subsequently formed source and drain.

In S140, the first metal layer 400/410/411/412/413 may be formed, as shown in steps e and f in FIG. 48, and steps e and f in FIG. 49.

The first metal film layer 400 may be prepared on a layer of the first insulating film layer away from the substrate, and the first metal film layer may be patterned and etched to form a first electrode 411, a first gate 412, and a second electrode 413.

The display panel may include a transistor, and the transistor may include the active layer, the first electrode, the first gate, and the second electrode. The first electrode and the second electrode may be electrically connected to the active layer, and the first gate may at least partially overlap with the active layer along the thickness direction of the substrate. It should be noted that for different transistors, the relative positions of the first electrode, the first gate, and the second electrode may be diverse, and the embodiments of the present disclosure may be not illustrated one by one here. The control signal received by the first gate of the transistor may be used to control the on or off of the transistor. The first electrode of the transistor may be one of the source electrode or the drain electrode, and the second electrode of the transistor may be the other of the source electrode or the drain electrode.

The position of the pattern of the first gate may avoid the opening of the insulating film layer to ensure the flatness of the first gate pattern and avoid the first gate extending to the side wall position of the opening of the insulating film layer.

The first metal layer may include the first electrode, the first gate, and the second electrode. That is, the first electrode, the first gate, and the second electrode in the transistor may be all prepared simultaneously using the same process when preparing the first metal layer. Compared with the process in which the preparation of the gate may be carried out separately from the preparation of the source/drain electrode, the process preparation cost of the display panel may be reduced. Furthermore, the first electrode, the first gate, and the third electrode may be all located on the side of the first insulating film layer away from the substrate, that is, the first gate, the first electrode, and the second electrode may be arranged in the same layer, which may be beneficial to realize the thin design of the display panel.

In S150, the first metal layer may be used as a mask to etch the first insulating film layer to form a first insulating layer 300, as shown in step g in FIG. 48 and step g in FIG. 49.

The first metal layer may be used as a mask to etch the first insulating film layer, the first insulating film layer covering the first metal layer may be retained, and the first insulating film layer not covered by the first metal layer may be etched. The etched first insulating film layer 300 may include a first insulating section 310 and a second insulating section 320. Along the thickness direction of the substrate, the first gate 412 may at least partially overlap with the first insulating section 310, and the first electrode 411 may at least partially overlap with the second insulating section 320.

Further, by using the first metal layer as a mask for etching, the morphology of the first insulating section may be similar to that of the first gate. That is, the cut-off position of the first gate may be the same as the cut-off position of the first insulating section, that is, the morphology of the first gate and the first insulating section may be consistent. The cut-off position of the first gate may be understood as the edge of the first gate pattern; and the cut-off position of the first insulating sub-section may be understood as the edge of the first insulating sub-section pattern. That is, the morphology of the edges of the first gate and the first insulating sub-section may be consistent, thus reflecting the regularity of the overall structure of the display panel.

Further, the morphology of the first insulating sub-section may be similar to that of the first gate, which may be understood as being achieved by the self-alignment process of the first gate. The first metal layer may be used as a mask to etch the first insulating film layer, that is, the first insulating layer that is not covered by the metal patterns of the first metal layer and exposed to the outside may be etched, to adjust the morphology of the first insulating sub-section, that is, to perform a self-alignment process to ensure that the edge morphology of the first gate and the first insulating sub-section is consistent. Optionally, when the self-alignment process is used and the first gate is used as a standard, there may be a process error when etching the first insulating sub-section. When the distance between the cut-off position of the first gate and the cut-off position of the first insulating sub-section is less than or equal to 0.5 microns, it may be considered that the cut-off position of the first insulating sub-section may be the same as the cut-off position of the first gate.

The first metal layer may include the first electrode, the first gate, and the second electrode. That is, the first electrode, the first gate, and the second electrode in the transistor may be all prepared simultaneously using the same process when preparing the first metal layer. Compared with the process in which the preparation of the gate may be carried out separately from the preparation of the source/drain electrode, the process preparation cost of the display panel may be reduced. Furthermore, the first electrode, the first gate, and the third electrode may be all located on the side of the first insulating film layer away from the substrate, that is, the first gate, the first electrode, and the second electrode may be arranged in the same layer, which may be beneficial to realize the thin design of the display panel.

On the first side, the cut-off position of the first gate may be the same as the cut-off position of the first insulating sub-section, that is, the edge of the first gate pattern may have the same morphology as the edge of the first insulating sub-section pattern, or it may be understood that the first gate and the first insulating sub-section have the same or similar shapes. The morphology of the first insulating sub-section may be adjusted according to the morphology of the first gate, such that the occupied area of the first insulating sub-section at the active layer may be reduced, that is, the exposed area of the active layer may be increased, and the exposed area may be again conductively set, that is, the area of the active layer that may be conductively increased, thereby improving the overall conductive properties and ensuring the working effect of the transistor in the display panel.

The adjustment of the shape of the first insulating section 310 may be formed by etching the first insulating layer 300 twice. After the first insulating layer 300 is etched for the first time, an opening y may be formed in the first insulating layer 300. After the opening y is formed in the first insulating layer 300 and before the first metal layer 400 is prepared, the active layer 200 may be firstly made conductive (such as ion doping). The region of the active layer 200 exposed by the opening y of the first insulating layer 300 may be made conductive to form a source region and a drain region, such that the source region and the drain region of the active layer may form good electrical contacts with the source and the drain formed subsequently. After the first conductive layer 200 is made conductive, the first electrode 411, the first gate 412, and the second electrode 413 in the transistor 410 may be formed. However, after the first etching, the cut-off position of the first insulating sub-portion 310 may be different from the cut-off position of the first gate 412. In the direction parallel to the plane where the substrate 100 is located, the size of the first insulating sub-portion 310 may be larger than the size of the first gate 412. For the portion of the active layer 200 covered by the first insulating sub-portion 310 and not overlapping with the first gate 412, the formed transistor will have a contact resistance problem. Since the portion of the active layer 200 is covered by the first insulating sub-portion 310, it is not conductive and may not play the role of a conductor in the source region or the drain region. Since the portion of the active layer 200 does not overlap with the first gate 412, it may not play the role of a channel region. The portion is located between the source region and the channel region and between the drain region and the channel region, so that the transistor has a contact resistance problem, and thus there is a situation where it may not be turned on normally. The first insulating layer 300 is etched for the second time by a self-alignment process, so that the portion of the active layer 200 may be exposed, which is conducive to improving the conductive properties of the portion of the active layer 200 by conducting it again. If the first insulating layer 300 is etched to a size of the first insulating sub-section 310 that is the same as the size of the first gate to be formed before the first metal layer 400 is prepared, the first gate is likely to cover the side wall of the first insulating sub-section when the first gate is formed. On the one hand, the first gate may not form a planar structure, which affects the function of the gate. On the other hand, the portion of the first gate extending to the side wall of the first insulating sub-section may contact the active layer, causing the transistor to fail. Therefore, the display panel 10 provided by the embodiment of the present invention and the process adjustment process of the first insulating layer 300 may improve the contact resistance problem of the transistor on the one hand, and may ensure the formation of a planar gate on the other hand, thereby reducing the occurrence of transistor failure.

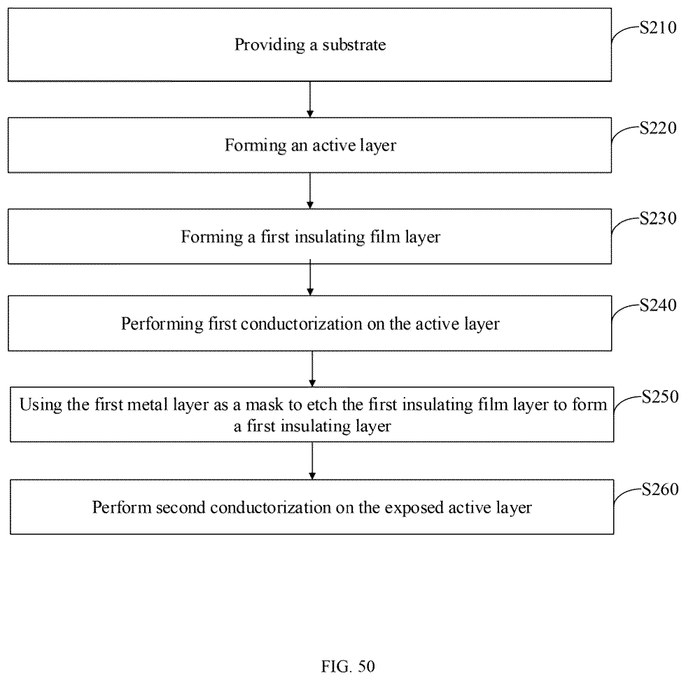

In another embodiment shown in FIG. 50 which is a flowchart of another fabrication method of a display panel, the method may further include S210 to S260.

In S210, a substrate 100 may be provided.

As shown in FIG. 49, a light shielding structure 710 may be formed on the substrate 100, and the light shielding structure 710 may have the effect of blocking light transmission. Further, the light shielding structure 710 may be disposed on the third metal layer 700, that is, the light shielding structure 710 may be located on the side of the first metal layer 400 close to the substrate 100.

In S220, an active layer 200 may be formed.

In S230, a first insulating film layer 300 may be formed.\

In S240, the active layer may be conductorized for the first time.

As shown in step d in FIG. 48 and step d in FIG. 49, the first insulating film layer prepared on the side of the active layer away from the substrate may include an opening, as shown in the area y marked in step d in FIG. 48, or referring to the area y1 and area y2 marked in step d in FIG. 49. That is, after the first insulating film layer is prepared, the first insulating film layer may be etched for the first time to form a corresponding opening. To ensure the electrical connection between the first electrode prepared subsequently and the active layer, the active layer may be firstly conductorized (ion doped) through the opening (area y1 marked in step d in FIG. 49), referring to the area indicated by 201 in step d in FIG. 49. For area y2 in step d in FIG. 49, the first gate prepared subsequently may be electrically connected to the light shielding structure, such that the prepared transistor may be a top-bottom double-gate transistor, providing the working stability of the transistor. Optionally, when the light shielding structure 710 is not prepared on the third metal layer 700 when preparing the transistor, it may be not necessary to design the opening at area y2 in step d in FIG. 49.

In S250, using the first metal layer as a mask, the first insulating film layer may be etched to form a first insulating layer.

In S260, the exposed active layer may be conductorized for the second time.

As shown in step g in FIG. 48 and step g in FIG. 49 the first insulation is formed, that is, when the first insulating section and the second insulating section are formed by using the first metal layer as a mask, the active layer may be secondly conductorized (or understood as the second ion doping of the active layer in this area). Specifically, as shown in step f and step g in FIG. 48 and step f and step g in FIG. 49, after the first metal film layer is etched for the second time using the first metal layer as a mask, the size and morphology of the first insulating section formed may be similar to the first gate, which is equivalent to reducing the space occupied by the first insulating film layer on the active layer. The additional space in the active layer may be conductorized for the second time, referring to the area indicated by 202 in step g of FIG. 49. It may be ensured that the overall conductive performance of the active layer is better, thereby improving the reliability of the electrical signal transmitted in the active layer, improving the contact resistance problem of the transistor, and ensuring the overall signal transmission effect of the display panel.

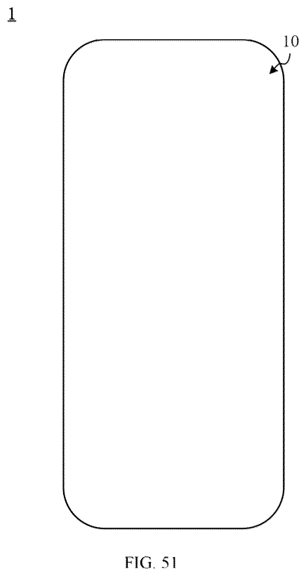

The present disclosure also provides a display device. In one embodiment shown in FIG. 51 which is a schematic diagram of a display device, the display device 1 may include any display panel 10 provided by various embodiments of the present disclosure. The display device may be an electronic device with a display function such as a cell phone, a tablet, a computer, a television, a smart wearable product (such as a smart watch), a vehicle display, etc.

In the present disclosure, relational terms such as “first” and “second” are only used to distinguish one entity or operation from another entity or operation, and do not necessarily require or imply that there is a relationship between these entities or operations. There is no such actual relationship or sequence. Furthermore, the terms “comprises”, “include”, or any other variations thereof are intended to cover a non-exclusive inclusion such that a process, method, article, or apparatus that includes a list of elements includes not only those elements, but also those not expressly listed, or elements inherent to the process, method, article or equipment. Without further limitation, an element defined by the statement “comprises a . . . ” does not exclude the presence of additional identical elements in a process, method, article, or apparatus that includes the stated element.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the disclosure. Thus, while the present disclosure has been described in detail with reference to the above described embodiments, the present disclosure is not limited to the above described embodiments, but may be embodied in other equivalent forms without departing from the scope of the present disclosure, which is determined by the appended claims.

What is claimed is:

1. A display panel, comprising:
a substrate;
an active layer on a side of the substrate;
a first insulating layer on a side of the active layer away from the substrate, wherein the first insulating layer includes a first insulating section and a second insulating section;
a first metal layer on a side of the first insulating layer away from the substrate, including a first electrode, a first gate and a second electrode,
wherein:
the display panel includes a transistor, wherein the transistor includes the active layer, the first electrode, the first gate and the second electrode;
the first electrode and the second electrode are both electrically connected to the active layer;
along a first direction, the first gate at least partially overlaps with the active layer, the first gate at least partially overlaps with the first insulating section, and the first electrode at least partially overlaps with the second insulating section, wherein the first direction is a direction perpendicular to a plane where the substrate is located;
the first gate includes a first side; and
on the first side, a cut-off position of the first gate is the same as a cut-off position of the first insulating section.

2. The display panel according to claim 1, wherein:
the first electrode includes a second side; and
on the second side, a cut-off position of the first electrode is the same as a cut-off position of the second insulating section.

3. The display panel according to claim 1, wherein:
in a first cross section, a cross section of the first gate is connected with a cross section of the first insulating section at a first edge, and the first edge is a line segment; wherein: the first cross section is a plane determined by a second direction and the first direction, and the second direction intersects the first side and is parallel to the plane where the substrate is located.

4. The display panel according to claim 1, wherein:
the active layer includes a channel region and a doped region, wherein the first gate overlaps with the channel region in the first direction; and
in the plane parallel to the plane where the substrate is located, along a third direction, the doped region is connected to the first gate at the first side of the first gate, wherein the third direction is parallel to the plane where the substrate is located and intersects with the first side.

5. The display panel according to claim 4, wherein:
the doped region includes a first doped section and a second doped section, wherein the second doped section is located between the first doped section and the channel region;
the first doped section is located on a side of the second doped section away from the channel region;
along the first direction, the first doped section at least partially overlaps with the first electrode; and
an ion doping concentration of the second doped section is equal to an ion doping concentration of the first doped section.

6. The display panel according to claim 1, further including a plurality of data signal lines and a plurality of scan signal lines, wherein:
the plurality of data signal lines is arranged along a fourth direction and extends along a fifth direction, and the plurality of scan signal lines is arranged along the fifth direction and extend along the fourth direction, wherein the fourth direction and the fifth direction intersect, and the fourth direction and the fifth direction are parallel to the plane where the substrate is located;
a data signal line of the plurality of data signal lines is electrically connected to the first electrode, and a scan signal line of the plurality of scan signal lines is electrically connected to the first gate; and
the plurality of data signal lines or the plurality of scan signal lines is located in the first metal layer.

7. The display panel according to claim 6, wherein:
the plurality of data signal lines is located in the first metal layer;
the display panel further includes a third metal layer on a side of the first metal layer close to the substrate; and
the plurality of scan signal lines is located in the third metal layer.

8. The display panel according to claim 7, further including a light shielding structure, wherein:
the light shielding structure includes a first light shielding pattern;
along the first direction, the first light shielding pattern at least partially overlaps with the active layer; and
the light shielding structure is located in the third metal layer.

9. The display panel according to claim 8, wherein:
the light shielding structure further includes a first light shielding extension pattern, and the first light shielding extension pattern connects the first light shielding pattern and the scan signal line;
the scan signal line includes a plurality of first sections and a plurality of second sections, wherein: the plurality of first sections and the plurality of second sections are arranged in sequence along the fourth direction; two adjacent first sections are electrically connected via one corresponding second section; along the fifth direction, a width of a first section of the plurality of first section is larger than a width of a second section of the plurality of second sections; along the first direction, the first section at least partially overlaps with the active layer, the second section does not overlap with the active layer; and the first section is multiplexed as the first light shielding pattern;
or
the scan signal line is provided with a plurality of hollow units, and the first light shielding pattern is located in a hollow unit of the plurality of hollow units.

10. The display panel according to claim 8, wherein:
the first metal layer further includes a plurality of metal blocks; and
along the fourth direction, a metal block of the plurality of metal blocks is located between two adjacent data signal lines, and along the first direction, the metal block overlaps with the scan signal line.

11. The display panel according to claim 7, further including a plurality of scan connection lines, wherein:
a scan connection line of the plurality of scan connetion lines is electrically connected to one corresponding scan signal line; and
the scan connection line is located in the first metal layer and extends along the fifth direction.

12. The display panel according to claim 6, wherein:
the data signal line includes a fifth section and a sixth section;
along the first direction, the fifth section at least partially overlaps with the active layer, and the sixth section does not overlap with the active layer; and
the fifth section is multiplexed as the first electrode.

13. The display panel according to claim 1, wherein:
the display panel has a display area and a non-display area, wherein the non-display area is located on at least one side of the display area;
the display panel also includes a plurality of signal lines located in the non-display area;
the plurality of signal lines includes a plurality of first signal lines and a plurality of second signal lines;
the plurality of first signal lines is arranged along a fourth direction and extends along a fifth direction;
the plurality of second signal lines is arranged along the fifth direction and extends along the fourth direction, wherein the fourth direction and the fifth direction intersect, and the fourth direction and the fifth direction are parallel to the plane where the substrate is located; and
the plurality of first signal lines or the plurality of second signal lines is located in the first metal layer.

14. The display panel according to claim 13, further including a fifth metal layer on a side of the first metal layer close to the substrate, wherein:
the plurality of first signal lines is located in the first metal layer; and
the plurality of second signal lines is located in the fifth metal layer.

15. The display panel according to claim 13, further including a driving circuit in the non-display region, wherein:
the plurality of first signal lines includes at least one of a common signal line, a high-level signal line, a low-level signal line, a clock signal line, a reset signal line, a start signal line or a ground line; and
the plurality of second signal lines includes a connecting line, and the driving circuit is electrically connected to first signal lines through the connecting line.

16. The display panel according to claim 1, further including an insulating layer and an electrode layer, wherein:
the insulating layer includes a planarization layer and a passivation layer;
the planarization layer is located on the side of the first metal layer away from the substrate, and the electrode layer is located on a side of the planarization layer away from the substrate;
the electrode layer includes a pixel electrode and a common electrode;
the pixel electrode is electrically connected to the second electrode;
the passivation layer includes a first passivation layer and a second passivation layer; and
the first passivation layer is located on a side of the planarization layer close to the first metal layer, and the second passivation layer is located between the pixel electrode and the common electrode.

17. The display panel according to claim 1, wherein:
the display panel is a liquid crystal display panel;
the liquid crystal display panel further includes a liquid crystal layer and a counter substrate;
the liquid crystal layer is located on a side of the first metal layer away from the substrate, and the counter substrate is located on a side of the liquid crystal layer away from the substrate.

18. A fabrication method of a display panel, comprising:
providing a substrate;
forming an active layer on a side of the substrate;
forming a first insulating film layer on a side of the active layer away from the substrate;
forming a first metal layer on a side of the first insulating film layer away from the substrate, wherein: the first metal layer includes a first electrode, a first gate, and a second electrode; the display panel includes a transistor and the transistor includes the active layer, the first electrode, the first gate, and the second electrode, the first electrode and the second electrode are both electrically connected to the active layer; and
using the first metal layer as a mask to etch the first insulating film layer to form a first insulating layer,
wherein:
the first insulating layer includes a first insulating section and a second insulating section; and
along a first direction, the first gate at least partially overlaps with the active layer, the first gate at least partially overlaps with the first insulating section, and the first electrode at least partially overlaps with the second insulating section, wherein the first direction is a direction perpendicular to the plane where the substrate is located.

19. The method according to claim 18, wherein:
the first insulating film layer has an opening, and the opening exposes at least a portion of the active layer; and
forming the first metal layer further includes: before forming the first metal layer, performing first conductorization on the active layer; and after forming the first insulating layer, performing second conductorization on the exposed active layer.

20. A display device comprising a display panel, wherein:
the display panel, includes:
a substrate;
an active layer on a side of the substrate;
a first insulating layer on a side of the active layer away from the substrate, wherein the first insulating layer includes a first insulating section and a second insulating section;
a first metal layer on a side of the first insulating layer away from the substrate, including a first electrode, a first gate and a second electrode,
wherein:
the display panel includes a transistor, wherein the transistor includes the active layer, the first electrode, the first gate and the second electrode;
the first electrode and the second electrode are both electrically connected to the active layer;
along a first direction, the first gate at least partially overlaps with the active layer, the first gate at least partially overlaps with the first insulating section, and the first electrode at least partially overlaps with the second insulating section, wherein the first direction is a direction perpendicular to a plane where the substrate is located;
the first gate includes a first side; and
on the first side, a cut-off position of the first gate is the same as a cut-off position of the first insulating section.
